(19) United States
(12) Patent Application Publication
(10) Pub. No.: US 2025/0038483 A1
(43) Pub. Date: Jan. 30, 2025

(54) OPTICAL DEVICES

(71) Applicant: DIFTEK LASERS, INC., Waterloo (CA)

(72) Inventor: Douglas R. DYKAAR, Waterloo (CA)

(21) Appl. No.: 18/226,821

(22) Filed: Jul. 27, 2023

(51) Int. Cl. H01S 5/34; H01S 5/026; H01S 5/04

(52) U.S. Cl. CPC H01S 5/34; H01S 5/0262; H01S 5/041

(57) ABSTRACT

There is provided an optical device to amplify an input light propagating along an optical path. The light source includes a substrate, and light emitters disposed on the substrate in the optical path. The light emitters each have a footprint on the substrate and extend away from the substrate laterally to the optical path. The light emitters each include a quantum well to emit an emitted light when the light emitter is electrically biased and exposed to the input light. The emitted light from the light emitters is to form an output light having an amplitude greater than a corresponding amplitude of the input light. Each pair of neighboring light emitters may be spaced from one another along the output path by a distance being about (q+¼)∧, where ∧ is the wavelength of the output light and q is an integer greater than or equal to zero.

### FIELD

The present specification relates to optical devices, and in particular to optical devices comprising one or more light emitters disposed on a substrate.

### BACKGROUND

Optical devices may use or manipulate light. This light may be generated by a light source. Some light sources may use solid-state light emitters to generate light.

### SUMMARY

According to an aspect of the present specification there is provided a light source to emit an output light along an output path, the light source comprising: a substrate; and a plurality of light emitters disposed on the substrate in the output path, the light emitters each having a footprint on the substrate and extending away from the substrate laterally to the output path, the light emitters each comprising a quantum well to emit the output light when the light emitter is electrically biased, the light emitters each having a refractive index higher than a corresponding refractive index of an environment outside of and abutting the light emitters; wherein: the light emitters each comprise a nanorod; and each pair of neighboring nanorods are spaced from one another along the output path by a distance being about λn/2, where λ is a wavelength of the output light and n is a natural number.

The light source may be to emit the output light along an output direction along the output path; a furthest upstream of the nanorods relative to the output direction may have at its upstream extremity a side wall forming an upstream optical interface; a furthest downstream of the nanorods relative to the output direction may have at its downstream extremity a corresponding side wall forming a downstream optical interface; and the downstream optical interface may be shaped to increase a transmission of the output light through the downstream optical interface relative to a corresponding transmission of the output light through the upstream optical interface.

The light source may further comprise a support material disposed on the substrate, the light emitters being at least partially embedded in the support material, the support material being substantially transparent to the output light, and the support material having a corresponding refractive index being smaller than the refractive index of the light emitters.

The support material may be a non-waveguide for the output light.

Outer boundaries of the support material may be non-totally-internally-reflective of the output light.

One or more of the outer boundaries may be one or more of: roughened to reduce reflectivity with respect to the output light; and angled to reduce reflectivity with respect to the output light.

The light emitters may terminate in respective ends opposite their footprints on the substrate, the ends extending out of the support material; and the light source may further comprise an electrical contact disposed on the support material and in electrical contact with the ends of the light emitters.

At least one of the nanorods may be to at least partially absorb the output light when the at least one nanorod is reverse-biased.

According to another aspect of the present specification there is provided a light source to emit an output light along an output path, the light source comprising: a substrate; and a light emitter disposed on the substrate in the output path, the light emitter having a footprint on the substrate and extending away from the substrate laterally to the output path, the light emitter comprising a quantum well to emit the output light when the light emitter is electrically biased, the light emitter having a refractive index higher than a corresponding refractive index of an environment outside of and abutting the light emitter, the footprint having a first extremity and a second extremity along the output path, the light emitter having an optical dimension being a distance between the first extremity and the second extremity along the output path, the optical dimension being about λn/2, where λ is a wavelength of the output light and n is a natural number; wherein the light emitter comprises a nanowall.

The light source may be to emit the output light along an output direction along the output path; the nanowall may have at its upstream extremity a side wall forming an upstream optical interface; the nanowall may have at its downstream extremity a corresponding side wall forming a downstream optical interface; and the downstream optical interface may be shaped to increase a transmission of the output light through the downstream optical interface relative to a corresponding transmission of the output light through the upstream optical interface.

The light source may further comprise one or more further light emitters each comprising a nanorod, the nanorods: being disposed on the substrate along the output path; and each pair of neighboring nanorods being spaced from one another along the output path by a corresponding distance being about λp/2, where λ is the wavelength of the output light and p is a natural number; and the nanowall being spaced from its one or more neighboring nanorods along the output path by a corresponding distance being about λm/2, where λ is the wavelength of the output light and m is a natural number.

The light source may be to emit the output light along an output direction along the output path; and a first number of the one or more nanorods upstream of the nanowall relative to the output direction may be larger than a second number of the one or more nanorods downstream of the nanowall relative to the output direction.

The light source may further comprise a support material disposed on the substrate, the one or more light emitters being at least partially embedded in the support material, the support material being substantially transparent to the output light, and the support material having a corresponding refractive index being smaller than the refractive index of the one or more light emitters.

The support material may be a non-waveguide for the output light.

Outer boundaries of the support material may be non-totally-internally-reflective of the output light.

One or more of the outer boundaries may be one or more of: roughened to reduce reflectivity with respect to the output light; and angled to reduce reflectivity with respect to the output light.

The light emitters may terminate in respective ends opposite their footprints on the substrate, the ends extending out of the support material; and the light source may further comprise an electrical contact disposed on the support material and in electrical contact with the ends of the light emitters.

At least one of the one or more nanorods may be to at least partially absorb the output light when the at least one nanorod is reverse-biased.

According to yet another aspect of the present specification there is provided an optical device to amplify an input light propagating along an optical path, the optical device comprising: a substrate; and a plurality of light emitters disposed on the substrate in the optical path, the light emitters each having a footprint on the substrate and extending away from the substrate laterally to the optical path, the light emitters each comprising a quantum well to emit an emitted light when the light emitter is electrically biased and exposed to the input light, the emitted light from the plurality of the light emitters to form an output light having an amplitude greater than a corresponding amplitude of the input light, and the light emitters each having a refractive index higher than a corresponding refractive index of an environment outside of and abutting the light emitters; wherein: the light emitters each comprise a nanorod; and each pair of neighboring nanorods are spaced from one another along the optical path by a distance being about (q+¼)∧, where ∧ is a wavelength of the input light and q is an integer greater than or equal to zero.

The optical device may further comprise a shell around one or more of the light emitters, wherein the one or more light emitters have a core-shell geometry.

The shell may be to reduce reflectivity of the light emitters of the input light.

The shell may have a thickness of about ∧/4 measured along the optical path.

The optical device may further comprise a support material disposed on the substrate, one or more of the light emitters being at least partially embedded in the support material, the support material being substantially transparent to the input light and the output light, and the support material having a corresponding refractive index being smaller than the refractive index of the light emitters.

The support material may be a non-waveguide for the input light and the output light.

Outer boundaries of the support material may be non-totally-internally-reflective of the input light and the output light.

One or more of the outer boundaries may be one or more of: roughened to reduce reflectivity with respect to the input light and the output light; and angled to reduce reflectivity with respect to the input light and the output light.

The light emitters may terminate in respective ends opposite their footprints on the substrate, the ends extending out of the support material; and the optical device may further comprise an electrical contact disposed on the support material and in electrical contact with the ends of the light emitters.

A subset of the light emitters furthest downstream along the optical path may be to absorb the output light and emit a corresponding electrical signal when the subset is reverse-biased.

A subset of the light emitters along the optical path may be to modulate the output light when the subset of the light emitters is reverse-biased.

The optical device may further comprise a cavity between two of the light emitters, the cavity in the optical path and open to a corresponding environment outside the optical device, the cavity to allow an analyte from the corresponding environment to enter the cavity and interact with one or more of the input light and the output light.

According to yet another aspect of the present specification there is provided a method of operating the optical device, the method comprising: defining the input light as an intensity band moving over time along the optical path; and, biasing a subset of the light emitters falling within the intensity band, the subset changing over time and along the optical path in alignment with the intensity band moving over time along the optical path.

The biasing the subset of the light emitters may comprise biasing the subset of the light emitters at a biasing amplitude that increases over time and along the optical path.

The method may further comprise: reverse biasing a corresponding subset of the light emitters furthest downstream along the optical path, the corresponding subset of the light emitters to absorb the output light and emit a corresponding electrical signal.

According to yet another aspect of the present specification there is provided a method of operating the optical device, the method comprising: biasing a first subset of the light emitters, the first subset to be exposed to the input light and emit the emitted light to form the output light; and reverse biasing a second subset of the light emitters, the second subset of the light emitters to at least partially absorb the output light.

The biasing the first subset of the light emitters may comprise biasing the first subset of the light emitters furthest upstream along the optical path; and the reverse biasing the second subset of the light emitters may comprise reverse biasing the second subset of the light emitters furthest downstream along the optical path, the second subset of the light emitters to absorb the output light and emit a corresponding electrical signal.

### BRIEF DESCRIPTION OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn are not necessarily intended to convey any information regarding the actual shape of the particular elements, and have been solely selected for ease of recognition in the drawings.

FIG. 1 shows a schematic side elevation view of an example light source, in accordance with a non-limiting implementation of the present specification.

FIG. 2 shows a top plan view of the light source of FIG. 1.

FIG. 3 shows a schematic side elevation view of another example light source, in accordance with a non-limiting implementation of the present specification.

FIG. 4 shows a top plan view of the light source of FIG. 3.

FIG. 5 shows a schematic side elevation view of yet another example light source, in accordance with a non-limiting implementation of the present specification.

FIG. 6 shows a top plan view of the light source of FIG. 5.

FIG. 7 shows a schematic side elevation view of yet another example light source, in accordance with a non-limiting implementation of the present specification.

FIG. 8 shows a top plan view of the light source of FIG. 7.

FIG. 9 shows a schematic side elevation view of yet another example light source, in accordance with a non-limiting implementation of the present specification.

FIG. 10 shows a top plan view of the light source of FIG. 9.

FIGS. 11A to 11E show schematic side elevation views of example stages of fabricating another example light source.

FIG. 12 shows a schematic side elevation view of an example optical device.

FIG. 13 shows a schematic top elevation view of an example optical device comprising a ring resonator.

FIG. 14 shows a schematic side elevation view of an example optical amplifier.

FIG. 15 shows a flowchart of an example method for operating an optical amplifier.

FIG. 16 shows a flowchart of another example method for operating an optical amplifier.

FIGS. 17A to 17C show an example scheme for biasing a subset of light emitters of an optical amplifier.

FIGS. 18A to 18C show another example scheme for biasing a subset of light emitters of an optical amplifier.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, and the like.

Moreover, in the following description, elements may be described as “configured to” perform one or more functions or “configured for” such functions. In general, an element that is configured to perform or configured for performing a function is enabled to perform the function, or is suitable for performing the function, or is adapted to perform the function, or is operable to perform the function, or is otherwise capable of performing the function.

It is understood that for the purpose of this specification, language of “at least one of X, Y, and Z” and “one or more of X, Y and Z” can be construed as X only, Y only, Z only, or any combination of two or more items X, Y, and Z (e.g., XYZ, XY, YZ, ZZ, and the like). Similar logic can be applied for two or more items in any occurrence of “at least one . . . ” and “one or more . . . ” language.

Unless the context requires otherwise, throughout the specification and claims which follow, the word “comprise” and variations thereof, such as, “comprises” and “comprising” are to be construed in an open, inclusive sense, that is as “including, but not limited to.”

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

The headings and Abstract of the Disclosure provided herein are for convenience only and do not interpret the scope or meaning of the implementations.

Use of solid-state light emitters may allow light sources to be manufactured at high volumes and relatively low per-unit cost. In some examples, semiconductor and microelectronics fabrication techniques may be used to manufacture such light sources. In addition, such light sources may be more easily fabricated on-chip, or otherwise integrated with electro-optical systems.

Moreover, in the size scales where quantum confinement comes into play, control over the physical dimensions of light emitters may provide an additional means of controlling the parameters of the output light generated by the light source. Examples of such parameters may include wavelength, wavelength distribution, and the like. Such size scales may include the nano-meter size scale, and the like. In some examples, the nano-meter size scale may range from ones to hundreds of nanometers. Moreover, nano-meter size scale may also be referred to as the nanometer size scale or the nanoscale. Furthermore, at such size scales the physical features of the light source may interact with the output light to provide additional functionality. Examples of such interactions may include Bragg reflection, and the like.

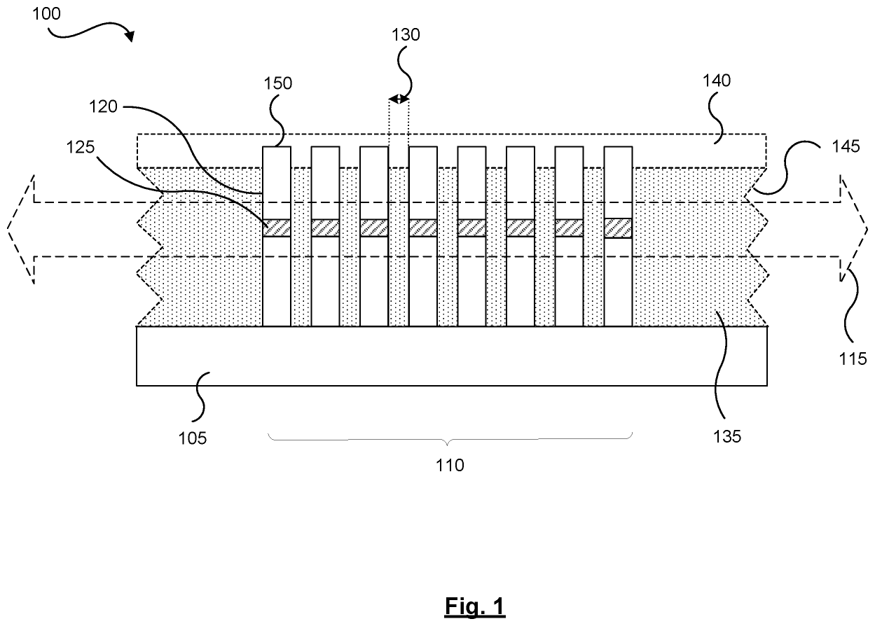

FIG. 1 shows a schematic side elevation view of an example light source 100, which light source uses solid-state light emitters. Light source 100 comprises a substrate 105 and a plurality of light emitter nanorods 110 disposed on substrate 105. In some examples, the substrate may comprise a silicon wafer, and the like. Light source 100 is to emit an output light along an output path 115. Nanorods 110 are disposed on substrate 105 along output path 115. Nanorods 110 each have a footprint on substrate 105 and extend away from substrate 105 laterally to output path 115. In some examples, a dimension of the footprint may be in the nanometer size scale. For example, in examples where the footprint is circular or about circular, the diameter of the footprint may be in the nanometer size scale. It is also contemplated that in come examples, the footprint may have a shape other than circular and that a dimension of the footprint other than the diameter may be in the nanometer size scale. It is also contemplated that in some examples, a dimension of the footprint may be larger than the nanometer size scale; for example, the dimension of the footprint may be measured in the single-digit micron scale, double-digit micron scale, and the like.

As shown in FIG. 1, nanorods 110 extend away from substrate 105 out of the plane defined by substrate 105. In FIG. 1, output path 115 is on a plane about parallel to the plane defined by substrate 105. It is also contemplated that in some examples, the output path may deviate from being about parallel to the plane of the substrate.

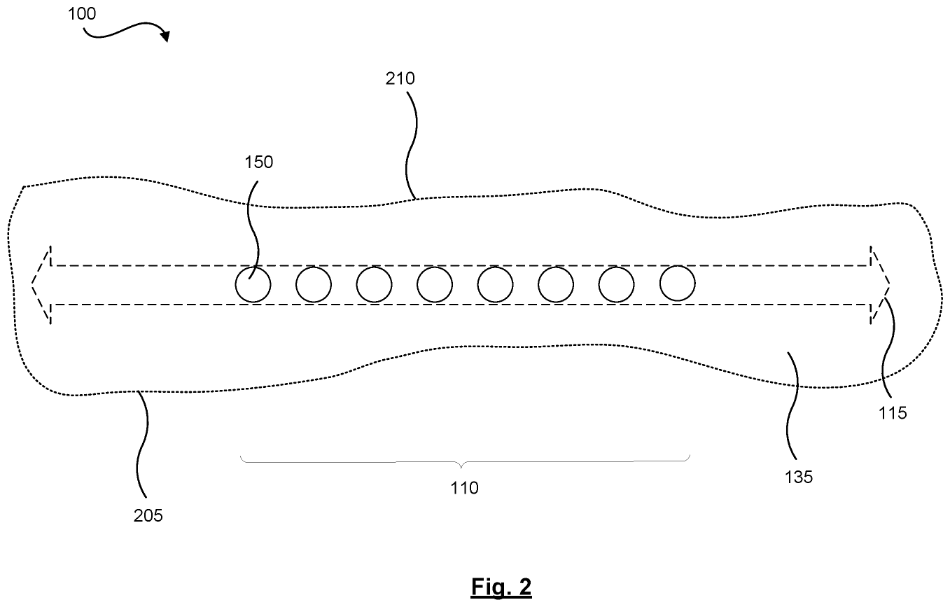

Nanorods 110 extending from the substrate laterally to output path 115 generally indicates “side emission” of the output light by nanorods 110. While FIG. 1 shows output path 115 being about perpendicular to the height of nanorods 110, it is contemplated that in some examples output path 115 may deviate from being perpendicular to the height of the nanorods. In some examples, output path 115 may deviate from being perpendicular to the height of the nanorods by up to about ±5°, by up to about ±10°, by up to about ±15°,by up to about ±20°, by up to about ±30°, by up to about ±40°, and the like. The footprint of nanorods 110 is show in and discussed further in relation to FIG. 2.

Each of nanorods 110 comprises a quantum well to emit the output light when the light emitter nanorod is electrically biased. Nanorod 120 is an example of nanorods 110. Nanorod 120 comprises quantum well 125. Other ones of nanorods 110 comprise a similar quantum well. Quantum well 125 may comprise a region or portion of nanorod 120 capable of emitting light when nanorod 120 and quantum well 125 are electrically biased. In some examples, quantum well 125 may comprise a semiconductor material. The electrical biasing may excite an electron across the energy levels (e.g. bandgap) of this semiconductor material. When this excited electron relaxes to a lower energy level, a photon of the output light may be emitted. It is also contemplated that in some examples, the light emitter(s) of the light source may comprise or form, instead of or in addition to the quantum wells, a quantum cascade laser geometry.

In some examples, the size of the footprint of nanorod 120 may exert a quantum confinement effect on quantum well 125, whereby the extent of quantum confinement affects the energy levels and the size of the bandgap of the quantum well. Using this quantum confinement effect, tailoring the size of the footprint of the nanorods may be used to tune the wavelength of the output light emitted by the light emitter nanorods. In addition, reducing the size of the footprint of nanorods 110 may allow crystal dislocations in nanorods 110 to more easily relax, thereby yielding higher quality light emitting materials.

In addition, while FIG. 1 shows quantum well 125 in the shape of a discrete band in the nanorods, it is contemplated that in some examples, the quantum well may have a different shape, size, or distribution in the light emitters such as nanorods 110. For example, each nanorod may comprise multiple bands or relatively larger quantum well bands, the quantum well may form or be part of a core-shell structure, and the like.

Light emitter nanorods 110 have a refractive index higher than a refractive index of the environment outside of and abutting nanorods 110. By the operation of Snell's Law, this relatively higher refractive index allows the emitted output light to be internally reflected by the light emitter nanorods and directed along the output path. In addition, in light source 100 each pair of neighboring nanorods 110 are spaced from one another along output path 115 by the Bragg Distance. The Bragg equation is as follows:

nλ=2dSinθ

Since the output light propagating along output path 115 is about perpendicular to nanorods 110 (i.e. θ is about 90°), Sinθ is about 1. As such, the Bragg Distance d can be expressed as nλ/2, where λ is the wavelength of the output light and n is a natural number. In other words, in light source 100 each pair of neighboring nanorods 110 are spaced from one another along output path 115 by a distance 130 being about nλ/2, where λ is the wavelength of the output light and n is a natural number.

This spacing allows for the light emitted by one of the nanorods to interfere constructively with and be in phase with and the light emitted by the other nanorods. This in turn, may allow light emission by one nanorod to stimulate emission from the other nanorods. In this manner, light source 100 may achieve coherent stimulated light emission or lasing. In addition, the choice of the Bragg spacing may also allow for selection and narrowing of the wavelength that is emitted by light source 100.

While FIG. 1 shows nanorods 110 as being the same distance from one another, it is contemplated that in some examples, the distance between different pairs of neighbouring nanorods may be different, so long as those distances are natural number multiples of λ/2. In other words, in some examples the nanorods need not be evenly spaced, so long as the spacing between pairs of neighboring nanorods is a natural number multiple of λ/2.

In addition, while in FIG. 1 distance 130 is marked between the outer walls of neighboring nanorods, it is contemplated that in some examples, distance 130 may be defined or measured between the center point of neighbouring nanorods. This center point may be the midpoint of the width of each of the nanorods, with the width being the dimension of each nanorod along output path 115. Moreover, in some examples, the width of each nanorod may also be a natural number multiple of λ/2. It is also contemplated that in some examples the nanorods may differ from one another in attributes such as their widths, shapes of their footprints, heights, and the like.

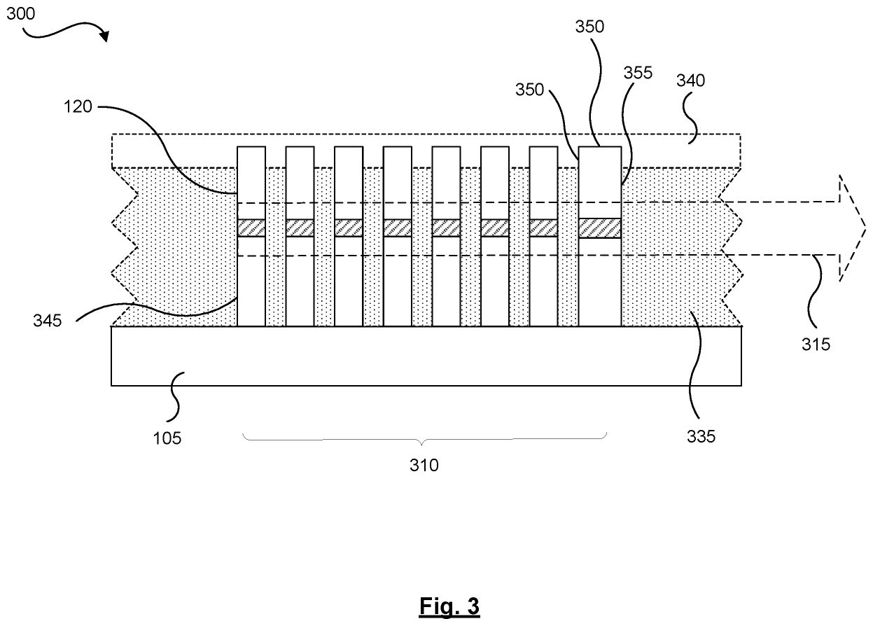

Since light source 100 is symmetrical in both directions along output path 115, light source 100 would emit light in both directions along output path 115. To guide or direct the output light in one of those directions, this symmetry of the structure of the light source may be reduced. Examples of such less symmetrical light sources are described in relation to FIGS. 3, 4, and 7-10.

Light source 100 also comprises a support material 135 on substrate 105. Light emitter nanorods 110 are partially embedded in support material 135, which is substantially transparent to the output light emitted by nanorods 110. In some examples, being substantially transparent may include being at least about 70% transparent, at least about 80% transparent, at least about 90% transparent, at least about 95% transparent, and the like.

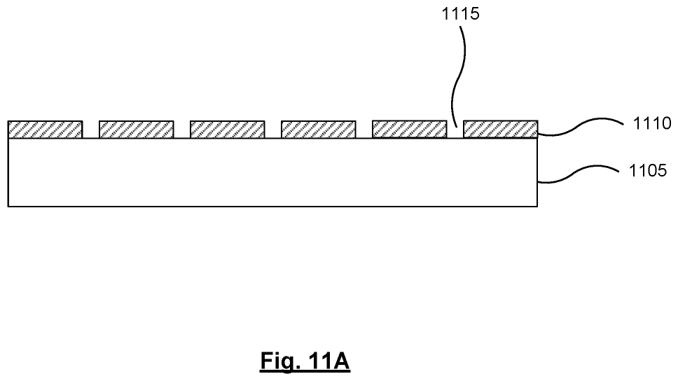

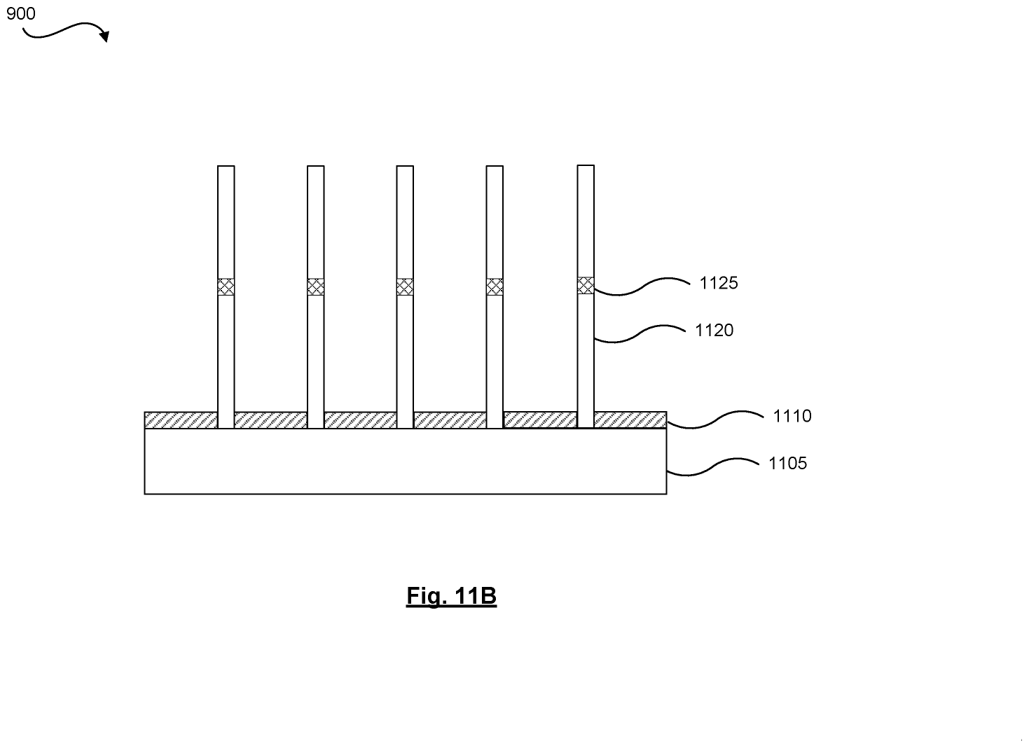

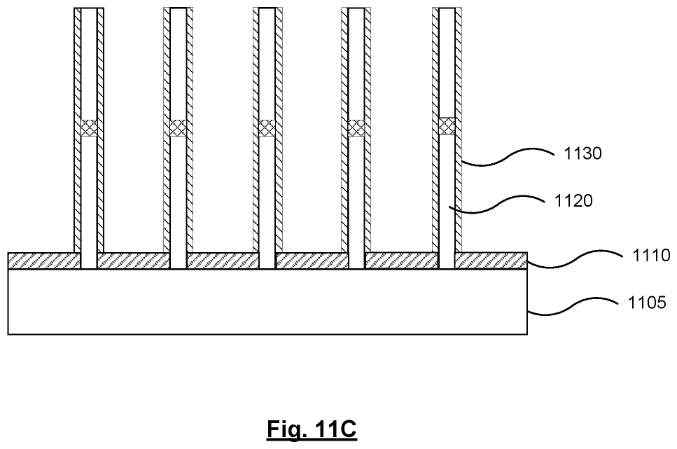

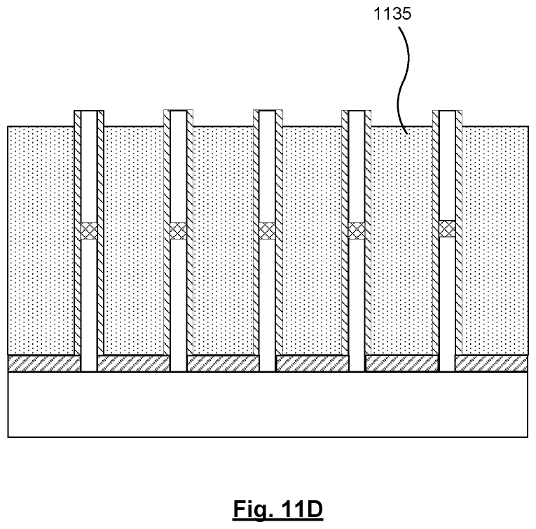

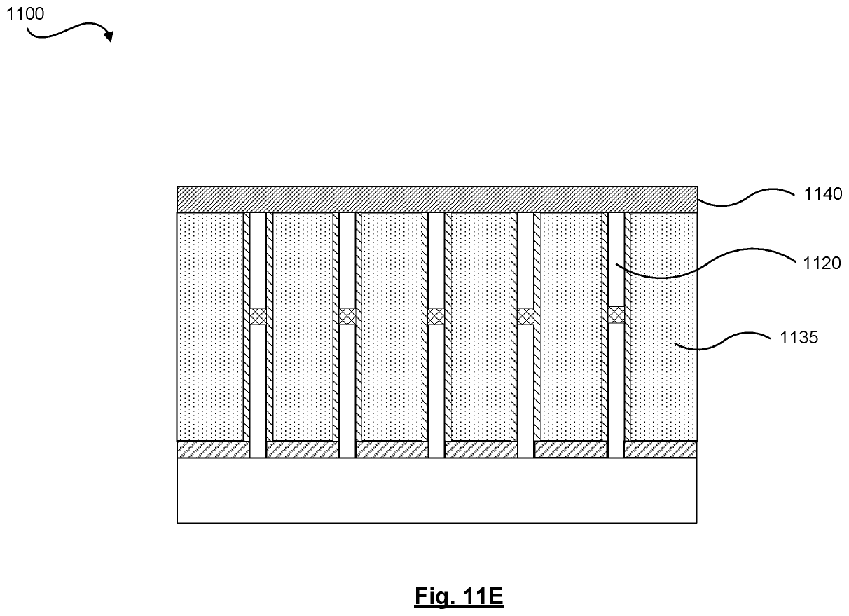

Support material 135 has a refractive index that is smaller than the refractive index of light emitter nanorods 110. In some examples, support material 135 may comprise a dielectric solid material such as SiN, SiO₂, and the like. Support material 135 may provide physical or mechanical support for nanorods 110. In addition, support material 135 may passivate the surface of nanorods 110. Such passivation may protect nanorods from being damaged by external agents. Support material 135 may also provide a support onto which an electrical contact 140 may be deposited or formed. Examples stages of formation of the nanorods and the support material, and also examples of passivation, are discussed further in relation to FIGS. 11A to 11E.

In FIG. 1, support material 135 is shown in dashed lines, to indicate that in some examples light source 100 need not comprise a solid support material. In some examples, air or another fluid may surround the nanorods.

In addition, in light source 100 support material 135 is a non-waveguide. In other words, support material 135 may be designed to have reduced or no ability to internally reflect the output light to guide the output light, particularly along the output path. As described above, light emitter nanorods 110 have a higher refractive index than the environment outside of the nanorods. In example light sources that have a solid support material, this environment may include the support material. The relatively higher index of refraction of the nanorods enables the nanorods to guide and direct the output light. Designing the support material to be a non-waveguide prevents redundancy or interference of the waveguiding of the support material with the wave guiding functionality of the nanorods.

In addition, in some examples, the light emitters of the light sources described herein may form a resonant cavity for the output light. Designing the support material to be a non-waveguide prevents the support material from acting as a second resonant cavity, which in turn may reduce or eliminate coupled cavity parasitics that could arise from a support material cavity interacting with the resonant cavity formed by the light emitters.

In some examples, to enhance the non-waveguide quality of the support material the outer boundaries of support material 135 may be non-totally-internally-reflective of the output light. In some such examples, one or more of the outer boundaries of the support material may be angled to reduce reflectivity with respect to the output light. In FIG. 1, boundaries 145 of support material 135 are angled in a zigzag pattern to reduce reflection of the output light and enhance the non-waveguide quality of support material 135. It is also contemplated that in some examples, shapes or angles other than zigzag may be used to reduce the reflectivity of the boundaries of the support material with respect to the output light.

Moreover, in some examples, instead of or in addition to being angled, one or more outer boundaries of the support material may be roughened to reduce reflectivity with respect to the output light. Other means of reducing reflectively or internal reflectivity of or at the outer boundaries of the support material are also contemplated, such as beam absorbers, beam dumps, and the like.

As shown in FIG. 1, light emitter nanorods 110 terminate in respective ends such as end 150. These ends are opposite the footprints of the nanorods on substrate 105. In light source 100, these ends extend out of support material 135. In some examples, etching (e.g. partial etching of the support material) or the like may be used to expose the nanorod ends. Light source 100 also comprises electrical contact 140 that is disposed on support material 135, and is in electrical contact with the ends of the light emitter nanorods 110. Electrical contact 140 may be used to bring electrical power to nanorods 110 to electrically bias nanorods 110 to emit the output light.

In FIG. 1 electrical contact 140 is shown in dashed lines to indicate that in some examples, light source 100 need not comprise electrical contact 140. In some such examples, the electrical contact may be on substrate 105 or located elsewhere in light source 100. In addition, it is contemplated that in some examples the ends of the nanorods need not extend out of the support material. In some such examples, the ends of the nanorods may be about flush with the support material or may be slightly recessed into the support material.

In addition, in some examples, in operation one or more nanorods 110 may at least partially absorb the output light when those nanorods are reverse-biased. This reverse biasing may be used to attenuate or turn off the output light emitted by the light source. In some examples, controlling this reverse biasing may be used to pulse or otherwise control the output light.

Turning now to FIG. 2, a top plan view of light source 100 is shown, looking through electrical contact 140. In FIG. 2 footprints of light emitter nanorods 110 on substrate 105 are shown. While FIG. 2 shows nanorods 110 as having circular footprints, it is contemplated that in some examples the nanorods may have a footprint of different shape, such as hexagonal, faceted, or other shapes. Moreover, while FIG. 2 shows all nanorods 110 as having the same footprint, in some examples the nanorods may have footprints that are different in characteristics such as shape, size, and the like.

In FIG. 2 sides 205 and 210 of support material 135 are shown as being irregularly shaped, to reduce reflections of the output light. In addition, the sides are shown in dashed lines to indicate that in some examples sides 205 and 210 may be otherwise angled, shaped, roughened, or distanced from the light emitters to reduce reflections of the output light.

FIG. 3 shows a schematic side elevation view of an example light source 300. Light source 300 is similar to light source 100, with a difference being that in light source 300 the symmetry along the output path has been reduced to allow light source 300 to preferentially emit the output light along one output direction 315 along the output path. In light source 300 this reduction in symmetry is achieved by changing the shape of the light emitter optical interface furthest downstream relative to output direction 315.

Light source 300 comprises light emitter nanorods 310, substrate 105, support material 335, and electrical contact 340. Nanorods 310 are generally similar to nanorods 110, with a difference being that in nanorods 310 the furthest downstream nanorod 350 relative to output direction 315 is different than the other nanorods. Support material 335 and electrical contact 340 are similar to support material 135 and electrical contact 140 respectively.

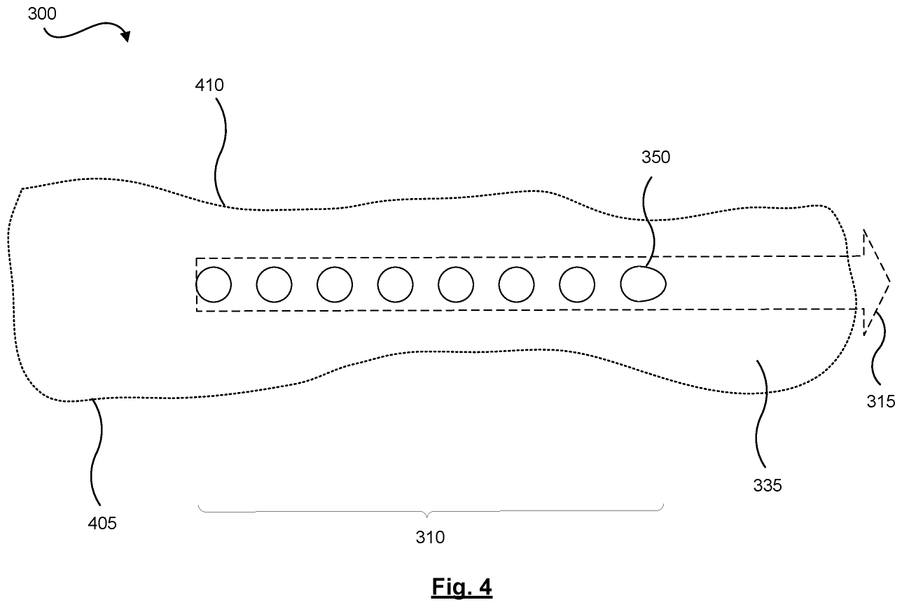

In light source 300, the further upstream of nanorods 310 relative to output direction 315 (i.e. nanorod 120) has at its upstream extremity a side wall 345 forming an upstream optical interface. Moreover, the furthest downstream of nanorods 310 relative to output direction 315 (i.e. nanorod 350) has at its downstream extremity a side wall 355 forming a downstream optical interface. In light source 300 the downstream optical interface is shaped differently than the upstream optical interface to change the transmission of the output light through the downstream optical interface relative to the transmission of the output light through the upstream optical interface. This change in shape is visible in FIGS. 3 and 4. This relative change in transmission of the output light allows for control over the direction along which the output light in emitted. In some examples, this change may comprise an increase in transmission of the output light through side wall 355.

As shown in FIG. 3, in light source 300 the relative change in light transmission at the downstream optical interface (i.e. side wall 355) has been achieved by changing the shape of side wall 355 to make it curved. Such a curvature may also provide a lensing effect, to further modify the output light. It is also contemplated that in some examples, the downstream optical interface may be changed in a different way, for example by changing attributes of the interface such as shape, angle, roughness, and the like.

Moreover, in some examples, the reflectivity of the output light at the upstream optical interface may be increased (thereby decreasing transmission) to control the direction of emission or propagation of the output light from light source 300. For example, portions of support material 335 abutting the upstream optical interface (e.g. side wall 345) may be removed to increase the difference or change in the refractive index between the upstream and downstream sides of the upstream optical interface. This increase in the change in the refractive index may in turn increase the reflectively of the upstream optical interface in relation to the output light.

Furthermore, in some examples, the width of the furthest upstream nanorod may be reduced to be much smaller than the wavelength of the output light. The width of the nanorod may be the dimension of the nanorod along output direction 315. In some examples where the nanorods have a circular footprint, the width may comprise the diameter of the nanorods.

In addition, in some examples, the upstream optical interface may comprise a grating reflector. Such a grating may be passive or active. In some examples, the grating may comprise curved elements, such as curved nanowalls and the like. Moreover, in some examples, the grating may comprise, or be formed from, the support material formed into a Bragg-spaced reflector array. In general, changing the transmission of the output light at the first optical interface (e.g. side wall 345) relative to the transmission at a second optical interface (e.g. side wall 355) may allow for controlling the direction of emission or propagation of the output light from light source 300.

FIG. 4 shows a schematic top plan view of light source 300, looking through electrical contact 340. Similar to FIG. 2, in FIG. 4 sides 405 and 410 of support material 335 shown to be irregularly shaped, to reduce reflectively with respect to the output light. In addition, the sides are shown in dashed lines to indicate that in some examples, sides 405 and 410 may be otherwise angled, shaped, roughened, distanced from the light emitters, and the like, in order to reduce reflectively with respect to the output light.

The light sources described herein can have a range of sizes and shapes. In some examples, the light source may define a rectangular prism having a length of about 0.5-1 mm along the output path, a width of about 1-2 μm, and rise above the substrate to a height of about 1 μm. Other shapes and sizes are also contemplated. In some examples where the light source comprises a non-waveguiding support material, the support material may have a width that is wider than about 5 μm, wider than about 10 μm, or the like. Moreover, in some examples, the sides or outer boundaries of such a support material may be oriented at an angle to the axial direction of the nanorods, which angle may be greater than a threshold. In some examples, this threshold may be about 1°, or another threshold greater than 1°.

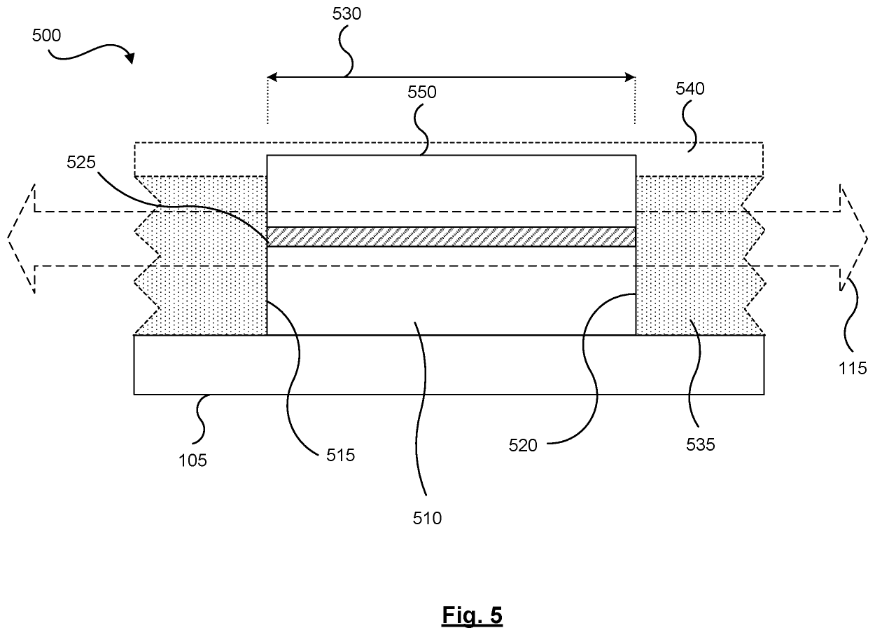

FIG. 5 shows a schematic side elevation view of another example light source 500. Light source 500 is similar to light source 100, with a difference being that the light emitter in light source 500 comprises a nanowall 510 while the light emitters in light source 100 are nanorods 110. Light source 500 comprises substrate 105, nanowall 510, support material 535, and electrical contact 540. Support material 535 and electrical contact 540 may be similar to support material 135 and electrical contact 140 respectively.

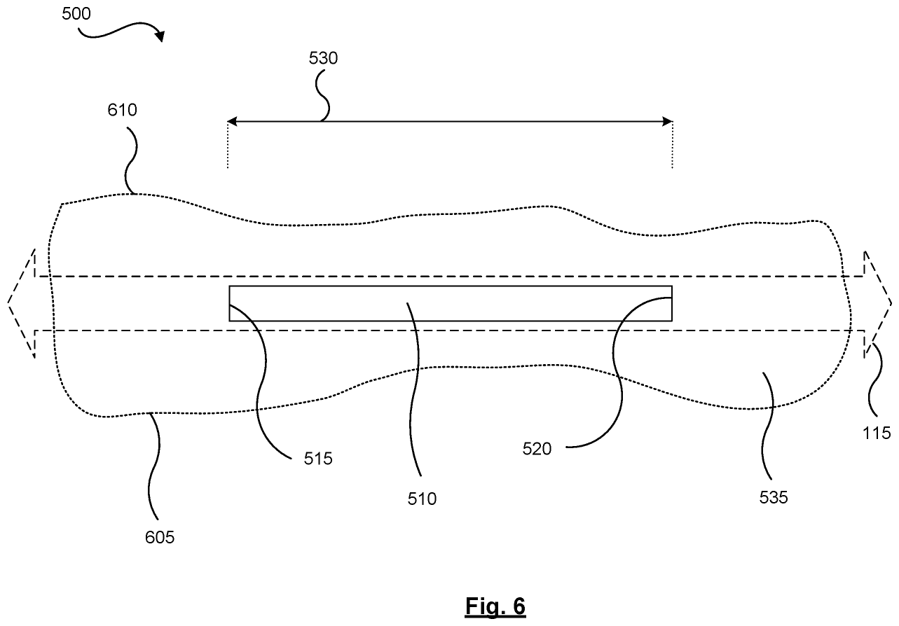

Nanowall 510 may comprise a quantum well 525, which may emit light when it is electrically biased. While quantum well 525 is shown as a layer extending along a direction about parallel to output path 115, it is contemplated that in some examples the quantum well may have a shape, size, or position in the nanowall different than those shown in FIG. 5. Nanowall 510 may have a width (visible in FIG. 6) that is in the nanometer size range.

In some examples, the nanowall may have a dimension that is in the nanometer size scale. For example, the width or thickness of the nanowall may be in the nanometer size scale. It is also contemplated that in some examples the nanowall may have a dimension that is larger; for example, the dimension may be in the single-digit micron scale, double-digit micron scale, and the like.

Nanowall 510 has a refractive index higher than the refractive index of the environment outside of and abutting the nanowall. In addition, the footprint of nanowall 510 has a first extremity 515 and a second extremity 520 along output path 115. These extremities comprise two of the side walls of nanowall 510. The distance between extremities 515 and 520 may be described as an optical dimension 530. Optical dimension 530 of nanowall 510 may be about λn/2, where λ is a wavelength of the output light and n is a natural number. In light source 500 nanowall 510 may act as a waveguide and form a resonant cavity for the output light between extremities 515 and 520. While FIG. 5 shows one nanowall, it is contemplated that in some examples the light source may comprise multiple nanowalls in the output path.

In other words, light source 500 comprises substrate 105 and a light emitter nanowall 510 disposed on substrate 105 in output path 115. Nanowall 510 has a footprint on substrate 105 and extends away from substrate 105 laterally to output path 115. Nanowall 510 comprises quantum well 525 to emit the output light when nanowall 510 is electrically biased. Nanowall 510 has a refractive index higher than a corresponding refractive index of an environment outside of and abutting nanowall 510. The footprint of nanowall 510 has first extremity 515 and second extremity 520 along output path 115. Nanowall 510 has optical dimension 530 being the distance between first extremity 515 and second extremity 520 along output path 115. Optical dimension 530 is about λn/2, where λ is the wavelength of the output light and n is a natural number.

In some examples, light source 500 also comprises support material 535 disposed on substrate 105. Support material 535 may have composition, structure, and function similar to those described in relation to support material 135. For example, the light emitter of light source 500 may be at least partially embedded in support material 535, which support material has a refractive index lower than the refractive index of the light emitter. In addition, support material 535 is a non-waveguide for the output light, in a manner similar to support material 135.

Nanowall 510 terminates in end 550 opposite its footprint on substrate 105. End 550 extends out of support material 535. Light source 500 comprises electrical contact 540 disposed on support material 535 and in electrical contact with end 550 of nanowall 510. Similar to light source 100, it is contemplated that in some examples end 550 may be flush with or recessed in support material 535. Moreover, similar to light source 100, it is contemplated that in some examples light source 500 need not comprise electrical contact 540 or a solid support material 535.

Turning now to FIG. 6, a top plan view of light source 500 is shown, looking through electrical contact 540. In FIG. 6 the footprint of light emitter nanowall 510 on substrate 105 is shown. While FIG. 6 shows nanowall 510 as having a rectangular footprint, it is contemplated that in some examples the nanowall may have a footprint of a different shape or size.

In FIG. 6, sides 605 and 610 of support material 535 are shown as being irregularly shaped, to reduce reflections of the output light. In addition, the sides are shown in dashed lines to indicate that in some examples sides 605 and 610 may be otherwise angled, shaped, roughened, or distanced from the light emitters to reduce reflections of the output light.

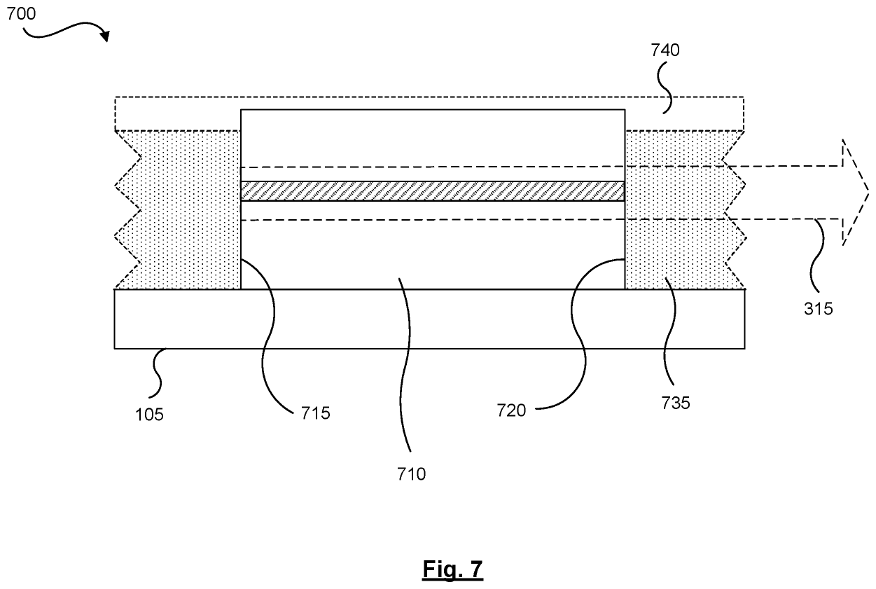

In order to control the direction of emission of the output light along the output path, one of the two extremities of the nanowall may be modified to modify transmission of the output light at one extremity relative to the transmission of the output light at the other extremity. FIG. 7 shows a schematic side elevation view of an example light source 700, where the direction of emission of the output light along the output path is controlled or tailored.

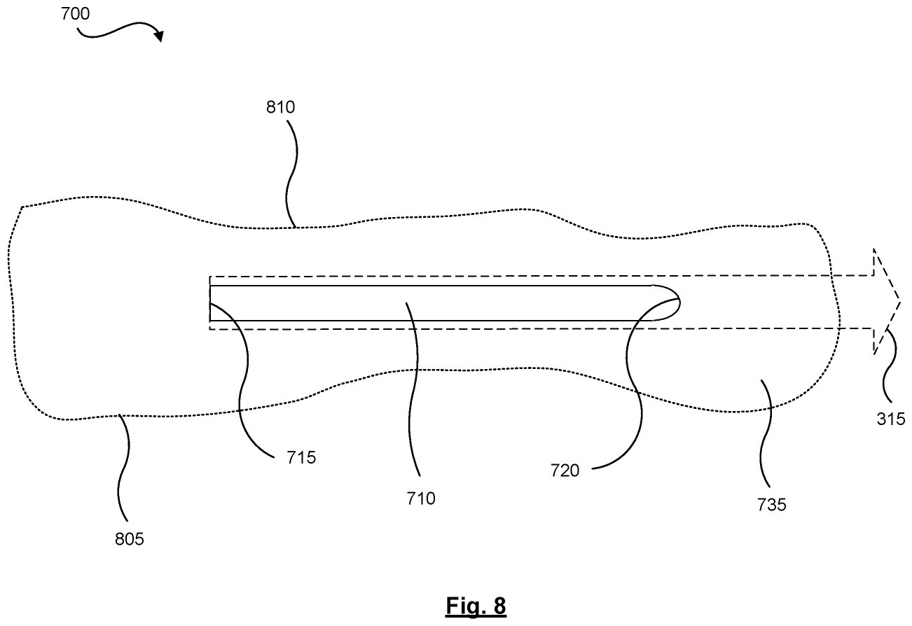

Light source 700 is similar to light source 500, with a difference being that in light source 700 optical interface at extremity 720 is shaped differently than the corresponding optical interface at extremity 520 of light source 500. This difference is clearly visible in FIG. 8. This change in shape changes transmission of the output light at extremity 720 compared to the transmission of the output light at extremity 715, thereby enabling light source 700 to emit the output light substantially along output direction 315. In some examples, this change comprises an increase in transmission of the output light through extremity 720.

Light source 700 comprises substrate 105, nanowall 710 having extremities 715 and 720 along output direction 315, support material 735, and electrical connector 740. Support material 735 and electrical connector 740 may be similar to support material 535 and electrical connector 540 respectively. Moreover, it is contemplated that in some examples light source 700 need not comprise a solid support material or electrical connector 740.

Nanowall 710 has at its upstream extremity 715 a side wall forming an upstream optical interface. Nanowall 710 also has at is downstream extremity 720 a corresponding side wall forming a downstream optical interface. The downstream optical interface is shaped to change transmission of the output light through the downstream optical interface relative to a corresponding transmission of the output light through the upstream optical interface. The shape of downstream extremity 720 is clearly visible in FIG. 8.

As shown in FIG. 7, in light source 700 the changed light transmission at the downstream optical interface (i.e. side wall or extremity 720) has been achieved by changing the shape of extremity 720 to make it curved. Such a curvature may also provide a lensing effect, to further modify the output light. It is also contemplated that in some examples, the downstream optical interface may be changed in a different way, for example by changing attributes of the interface such as shape, angle, roughness, and the like. In some examples, the transmission of the output light at the upstream optical interface relative to the transmission at the downstream optical interface may be modified using approaches similar to those described in relation to FIG. 3. In general, changing the transmission of the output light at the upstream optical interface (e.g. extremity 715) relative to the transmission at the downstream optical interface (e.g. extremity 720) may allow for controlling the direction of emission or propagation of the output light from light source 700.

Turning now to FIG. 8, a top plan view of light source 700 is shown, looking through electrical contact 740. In FIG. 8, sides 805 and 810 of support material 735 are shown as being irregularly shaped, to reduce reflections of the output light. In addition, the sides are shown in dashed lines to indicate that in some examples sides 805 and 810 may be otherwise angled, shaped, roughened, or distanced from the light emitters to reduce reflections of the output light.

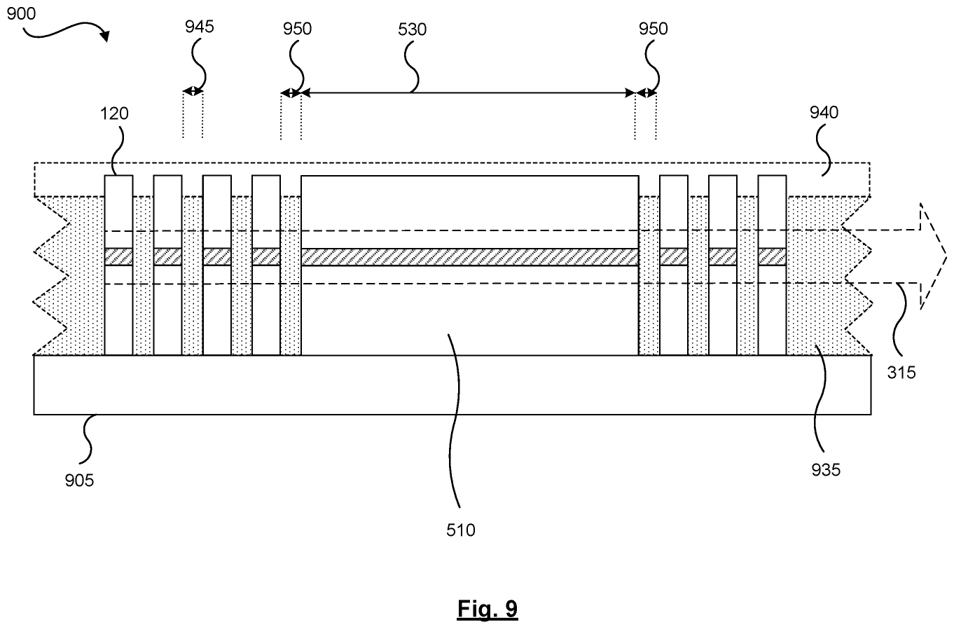

In addition to changing the shape of the upstream or downstream optical interfaces, other ways of reducing symmetry may also be used to control the direction of emission of the output light from a light source. One such way is to use both a nanowall and nanorods as light emitters, and to asymmetrically distribute the nanorods on the substrate on either side of the nanowall along the output path. If the nanorods are spaced from the nanowall and from one another at natural number multiples of the Bragg Distance, the nanorods may act as at least a partial Bragg mirror to at last partially reflect the output light propagating along the output path. The larger the number of nanorods, the higher the reflectivity of such a Bragg mirror. If the number of nanorods upstream of the nanowall relative to the output direction is larger than the number of nanorods downstream of the nanowall relative to the output direction, the side with the larger number of nanorods may act substantially as the back mirror and the side with the fewer nanorods may act substantially as the optical output interface through which the output light is emitted by the light source. FIG. 9 shows an example of such a light source.

FIG. 9 shows a schematic side elevation view of yet another example light source 900, which comprises a substrate 905, nanowall 510, support material 935, and electrical contact 940. Substrate 905, support material 935, and electrical contact 940 are similar to substate 105, support material 535, and electrical contact 540 respectively. Light source 900 is similar to light source 500, with a difference being that light source 900 further comprises light emitter nanorods 120 each being disposed on substrate 905 along the output path as indicated by output direction 315. Light source 900 comprises seven nanorods, which are similar to, or the same as, one another in composition, structure, and function.

Each pair of neighboring nanorods is spaced from one another along the output path by a distance 945 being about λp/2, where λ is the wavelength of the output light and p is a natural number. In addition, nanowall 510 is spaced from its neighboring nanorods along the output path by a corresponding distance 950 being about λm/2, where λ is the wavelength of the output light and m is a natural number. While in FIG. 9 distances relative to a nanorod are measured from an outer surface or side wall of the nanorod, it is contemplated that in some examples the distances may be measured from the center point of the nanorods. In addition, while FIG. 9 shows distances 945 between pairs of nanorods as being equal, and also being equal to distances 950, it is contemplated that in some examples these distances need not be equal to one another so long as the distances are about natural number multiples of λ/2.

Light source 900 emits output light substantially long output direction 315 along the output path. Light source 900 has four nanorods upstream of nanowall 510 relative to output direction 315 and fewer nanorods, namely three, downstream of nanowall 510 relative to output direction 315. The relatively larger number of nanorods on the upstream side of nanowall 510 makes the upstream side more reflective and less transmissive of the output light relative to the downstream side. This relative difference in transmission of the output light allows light source 900 to emit light substantially along output direction 315.

While FIG. 9 shows light source 900 as having four nanorods upstream and three nanorods downstream of nanowall 510, it is contemplated that in some examples different numbers of nanorods on either the upstream or downstream side of the nanowall may be used. In addition, while FIG. 9 shows light source 900 as having one nanowall and multiple nanorods, it is contemplated that in some examples the light source may have different numbers, combinations, and distributions of nanowalls, nanorods, and other types, structures, or shapes of solid state light emitters.

In some examples, one or more of the nanorods in light source 900 may be used to absorb the output light when those nanorods are reverse-biased. This light absorption may be used to control the output light, for example to pulse the output light, and the like. It is also contemplated that in some examples the nanowall may also be reverse biased to absorb the output light.

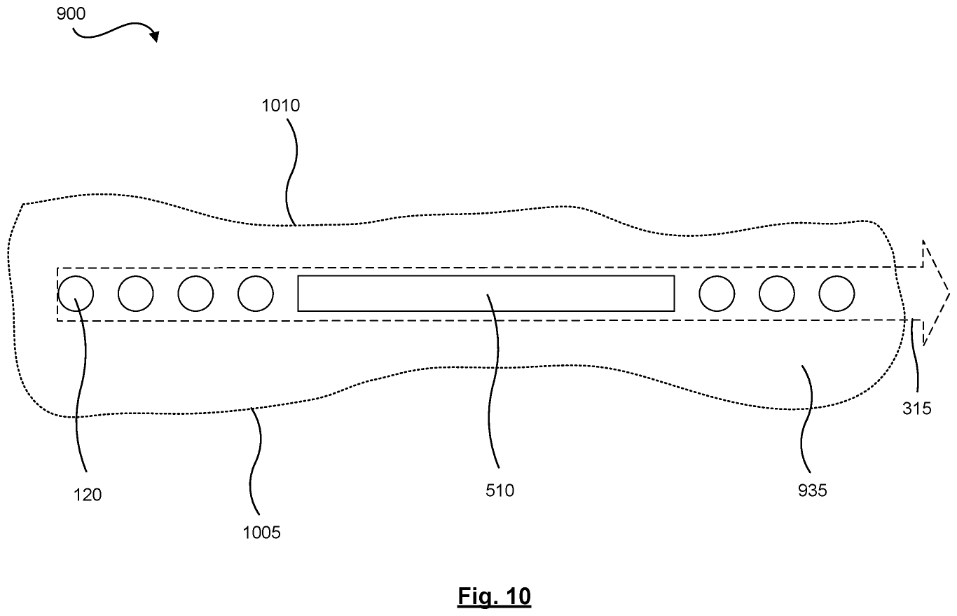

Turning now to FIG. 10, a top plan view of light source 900 is shown, looking through electrical contact 940. In FIG. 10 the footprint of light emitter nanowall 510 and the light emitter nanorods on substrate 905 are shown. While FIG. 10 shows nanowall 510 as having a rectangular footprint and the nanorods as having circular footprints, it is contemplated that in some examples the nanowall or the nanorods may have footprints of different shapes or sizes.

In addition, in FIG. 10, sides 1005 and 1010 of support material 935 are shown as being irregularly shaped, to reduce reflections of the output light. In addition, the sides are shown in dashed lines to indicate that in some examples sides 1005 and 1010 may be otherwise angled, shaped, roughened, or distanced from the light emitters to reduce reflections of the output light.

Turning now to FIGS. 11A to 11E, schematic side elevation views are shown of example stages of fabricating another example light source 1100. Light source 1100 is shown in FIG. 11E. Light source 1100 may function in a manner similar to light source 100, and may have components similar to those of light source 100. FIG. 11A shows a side elevation view of a substrate 1105 of light source 1100. Substrate 1105 may be similar to substrate 105. A patterned mask 1110 is formed on substrate 1105. In some examples, mask 1110 may comprise a refractive metal material, and the like. The pattern of mask 1110 leaves gaps 1115 on substrate 1105, in which gaps the nanorods may be formed.

FIG. 11B shows nanorods 1120 formed on substrate 1105 in the gaps in mask 1110. Each nanorod 1120 comprises a corresponding quantum well 1125. Nanorods 1120 and quantum wells 1125 may be similar to nanorod 120 and quantum well 125 respectively. Nanorods 1120 may be formed using suitable deposition or growth techniques such vacuum-based techniques, and the like.

FIG. 11C shows a shell 1130 formed on each of nanorods 1120. Such a shell may also be formed using suitable deposition or growth techniques such vacuum-based techniques, and the like. Shell 1130 may be used to passivate nanorods 1120. In some examples, shell 1130 may also be used to control optical properties at the interface of nanorods 1120 with the surrounding materials. For example, shell 1130 may be used to control reflectivity at the surface of the nanorods by controlling properties of shell 1130 such as its refractive index and thickness. In some examples, shell 1130 may be designed to be a reflectivity-reducing layer for parasitic or otherwise undesirable wavelengths. In some such examples, shell 1130 may be designed to be a one-quarter wavelength layer to act as an anti-reflective layer for any undesirable wavelengths.

FIG. 11D shows a support material 1135 deposited in the spaces between the core-shell nanorods. Support material 1135 may be similar to support material 135. In some examples, support material 1135 may be deposited using a vacuum-based technique. It is also contemplated that in some examples, after the formation of shells 1130 the vacuum may be broken and support material 1135 may be deposited using a non-vacuum-based technique.

While in FIGS. 11C and 11D mask 1110 is shown as remaining on substrate 1105 after shell 1130 is formed and support material 1135 is deposited, it is contemplated that in some examples mask 1110 may be selectively removed either before shell 1130 is formed, or after shell 1130 is formed and before support material 1135 is deposited.

FIG. 11E shows an electrical contact 1140 formed on support material 1135 and in contact with nanorods 1120. Electrical contact 1140 may be similar to electrical contact 140. Electrical contact 1140 may be used to electrically power or bias nanorods 1120. In some examples, the stages of formation of the light source described in relation to FIGS. 11A to 11E and light source 1100 may also apply to the other optical devices described herein, including light sources comprising nanorods, light sources comprising one or more nanowalls, and light sources comprising a combination of one or more nanowalls and one or more nanorods.

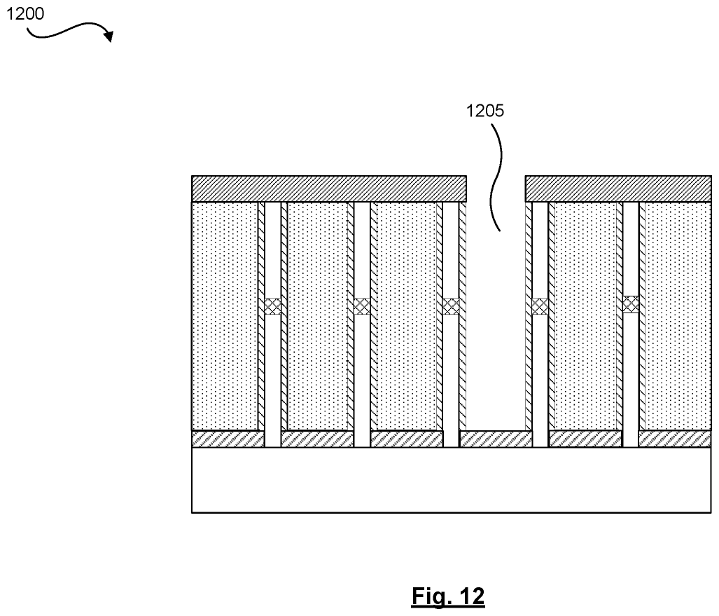

Turning now to FIG. 12, a schematic side elevation view is shown of an example optical device 1200. Optical device 1200 is similar to light source 1100, with a difference being that in optical device 1200 a space 1205 between two neighboring nanorods is not filled with the support material. Space 1205 is open to the environment surrounding optical device 1200, potentially allowing materials in the environment to enter space 1205 and interact with the light propagating inside optical device 1200. This interaction, in turn, may allow material from the environment to affect the light output by optical device 1200. Monitoring the affects of such interactions on the output light may allow optical device 1200 to act as a sensor. It is contemplated that in some examples, leaving one or more open spaces similar to space 1205 may also be applied to the other light sources described herein, including light sources comprising nanorods, light sources comprising one or more nanowalls, and light sources comprising a combination of one or more nanowalls and one or more nanorods.

In the optical devices (including light sources and sensors) described herein in relation to FIGS. 1 to 12, the path of the light is shown as being linear. It is also contemplated that in some examples, the light emitters may be arranged such that the optical path is a closed shape forming a “ring resonator”. Examples of such a closed shape may include a circle, an oval, and the like. Optical devices having “ring resonator” geometries may also be used for sensing, including sensing using cavity ring down spectroscopy, and the like.

In some examples, such “ring resonator” geometries may also include one or more of an optical inlet for injecting light into the ring resonator and an optical outlet for outputting light from the ring resonator. Moreover, in some examples, the “ring resonator” geometries may be applied to the light sources described herein, including light sources comprising nanorods, light sources comprising one or more nanowalls, and light sources comprising a combination of one or more nanowalls and one or more nanorods.

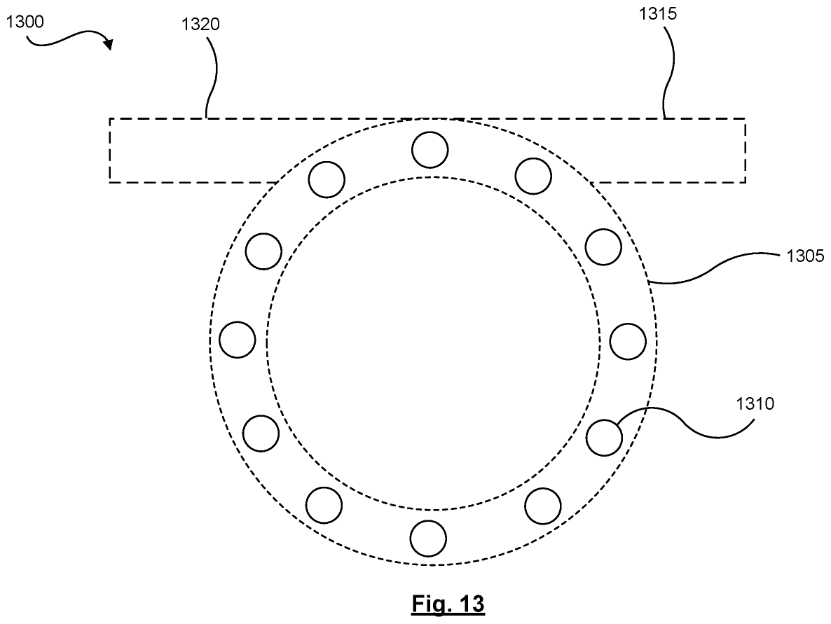

FIG. 13 shows a schematic top elevation view of an example optical device 1300 comprising a ring resonator 1305. In some examples, ring resonator 1305 may have a diameter in the millimeter to centimeter size scale. Other size ranges and scales are also contemplated. Ring resonator 1305 is formed using a plurality of nanorod light emitters 1310 disposed on a substrate. Nanorod light emitters 1310 and their substrate may be similar respectively to nanorods 120 and substrate 105, and to the other nanorods and substrates described herein. A difference between optical device 1300 and light source 100 is that in optical device 1300 the nanorod light emitters are arranged along a circle such that the optical path of the light passing through the nanorod light emitters is about circular. In this manner, nanorods 1310 can form a ring resonator 1305.

Optical device 1300 may also comprise an optical inlet 1315 for injecting a light into ring resonator 1305 and an optical outlet 1320 for outputting light from ring resonator 1305. In FIG. 13 optical inlet 1315 and outlet and 1320 are shown in dashed lines to signify that in some examples the optical device need not comprise one or more of the optical inlet or outlet, or that one or more of the optical inlet and outlet may have a shape, size, or position relative to ring resonator 1305 that are different from the shape, size, and positions shown in FIG. 13.

It is contemplated that in some examples optical device 1300 may have properties or functions similar to those of the other light sources and optical devices described herein. It is also contemplated that in some examples, optical device 1300 may comprise, instead of or in addition to some or all of nanorods 1310, other types of light emitters such as nanowalls and the like. In some examples, optical device 1300 may be used for sensing, including sensing using cavity ring down spectroscopy, and the like.

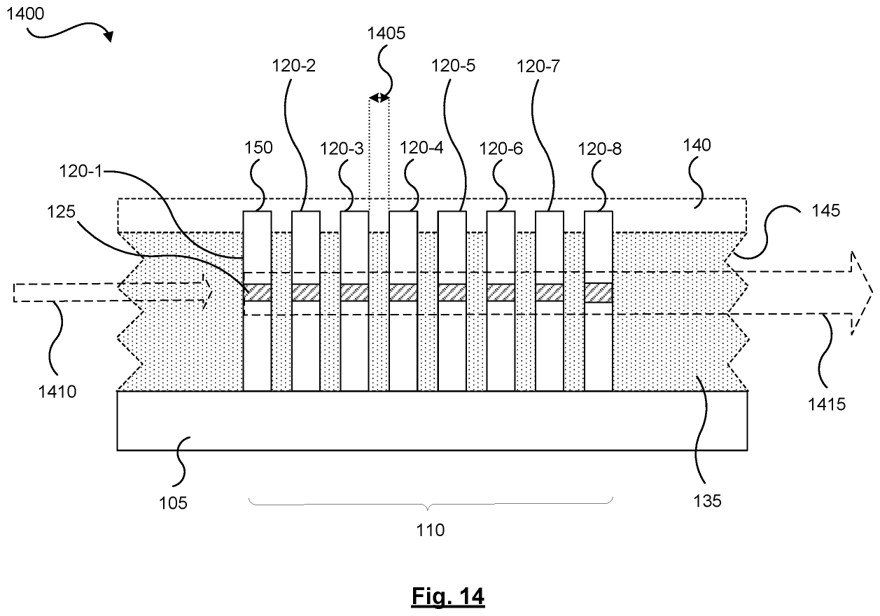

In the optical devices described in relation to FIGS. 1-13, the light emitters are electrically biased, and then emit light. These optical devices may have different functions such as functions as light sources, sensors, and the like. In some examples, the light emitters may be electrically biased, and then exposed to an input light. The input light may then stimulate or cause the biased light emitters to emit light. This emitted light may have the same wavelength and k-vector as the input light. The stimulated emitted light from the light emitters may form an output light having an amplitude or intensity greater than the input light. In this manner, the optical device may be used as an optical amplifier. FIG. 14 shows an example of such an optical amplifier.

FIG. 14 shows a schematic side elevation view of an example optical amplifier 1400. Amplifier 1400 may be similar to light source 100, with amplifier 1400 comprising a plurality of nanorod light emitters 120-1, 120-2, 120-3, 120-4, 120-5, 120-6, 120-7, and 120-8 disposed on substrate 105. For greater clarity, the nanorods in amplifier 1400 may be the same as the nanorods in light source 100; in particular, nanorod 120-1 in amplifier 1400 is the same as nanorod 120 in light source 100, and the difference in component number is intended for ease of description in relation to FIG. 14. A difference between amplifier 1400 and light source 100 is that in amplifier 1400 a distance 1405 between neighboring nanorod light emitters is different than distance 130 in light source 100. This difference is described in greater detail below.

Amplifier 1400 may function to amplify an input light 1410 to form an output light 1415. The arrow showing input light 1410 in FIG. 14 indicates the optical path along which input light 1410 may be travelling or propagating. Amplifier 1400 comprises substrate 105 and a plurality of light emitters 120-1 to 120-8 disposed on substrate 105 in the optical path. While FIG. 14 shows eight light emitters, it is contemplated that amplifier 1400 may comprise a smaller or larger number of light emitters.

The light emitters each have a footprint on substrate 105 and extend away from substrate 105 laterally to the optical path. The light emitters each comprise a corresponding quantum well 125 to emit an emitted light when the light emitter is electrically biased and exposed to input light 1410. The emitted light from the plurality of the light emitters may form output light 1415 having an amplitude greater than a corresponding amplitude of input light 1410. In some examples, the emitted light from the light emitters may combine to form output light 1415. Moreover, in some examples, output light 1415 may comprise a superposition, in terms of amplitude or intensity, of the emitted light from the light emitters. In this manner, amplifier 1400 may amplify input light 1410 to form output light 1415.

The light emitters may each have a refractive index higher than a corresponding refractive index of an environment outside of and abutting the light emitters. This may help to substantially retain the optical energy of input light 1410, the emitted light, and output light 1415 propagating within amplifier 1400 along the optical path and close to the light emitters. In this manner, the position of the light emitters may function to define the optical path.

In addition, to facilitate input light 1410 propagating through amplifier 1400 to stimulate the electrically-biased light emitters to emit the emitted light, the spacing or distance between the light emitters may be set to reduce or minimize reflections of the input light (or of the emitted and output lights which have the same wavelength as the input light) at the surfaces of the light emitters along the optical path. In some examples, the distance between light emitters may be set at the Bragg minimum. In other words, each pair of neighboring nanorods may be spaced from one another along the optical path by a distance being about (q+¼)∧, where ∧ is a wavelength of the input light and q is an integer greater than or equal to zero. In yet other words, distance 1405 may be about (q+¼)∧, where ∧ is a wavelength of the input light and q is an integer greater than or equal to zero. In this way, distance 1405 may be different than distance 130 in light source 100.

Moreover, in some examples, to help reduce or minimize reflections of the input light (or of the emitted and output lights which have the same wavelength as the input light) at the surfaces of the light emitters along the optical path, nanorod surfaces may be tilted at about Brewster's angle to minimize reflections, which may be effective particularly for polarized input light signals.

The spacing between the light emitters may also be tuned according to the wavelength of input light 1410. In other words, the spacing may be set to be at about the Bragg minimum for the wavelength of the input light. In this manner, the input light (and the emitted and output lights which have the same wavelength as the input light) may propagate through amplifier 1400 while facing reduced or minimum reflections at the surfaces of the light emitters in the optical path. Other, parasitic, wavelengths may be reflected at a relatively greater degree at the surfaces of the light emitters. As such, these parasitic wavelengths may be attenuated or at least partially filtered out by selecting the spacing between the light emitters.

Moreover, as shown in FIG. 14, the light emitters may comprise nanorods. It is also contemplated that in some examples, the amplifier may comprise, in addition or instead of one or more of the nanorods, light emitters having shapes other than nanorods. Some examples of light emitters having other shapes may include nanowalls, and the like. Some or all of the structures or geometries described in relation to FIGS. 2-13 may also be used to implement optical amplifiers, provided the distance between neighboring light emitters or neighboring optically reflective interfaces is adjusted to reduce or minimize reflections at the wavelength of the input light.

In addition, in some examples, the amplifier may comprise a shell around one or more of the light emitters, such that the light emitter may have a core-shell geometry. An example of such an architecture is described in relation to FIGS. 11A-11E. Furthermore, in some examples, such a shell may function to reduce the reflectivity of the light emitters at the wavelength of the input light. In other words, the shell may reduce the reflectivity of the light emitters of the input light. Moreover, in some examples, the shell may have a thickness of about/4 measured along the optical path.

Furthermore, the amplifier may also comprise a support material disposed on the substrate. FIG. 14 shows support material 135 disposed on substrate 105. The properties and functions of this support material in the context of the amplifier may be the same as the properties and functions of the corresponding support materials described in relation to the optical devices described in relation to FIGS. 1-13.

In some examples, one or more of the light emitters may be at least partially embedded in the support material, and the support material may be substantially transparent to the input light and the output light. Moreover, the support material may have a corresponding refractive index that is smaller than the refractive index of the light emitters.

Furthermore, in some examples, the support material may be a non-waveguide for the input light and the output light. For example, outer boundaries of the support material may be non-totally-internally-reflective of the input light and the output light. In some examples, one or more of such outer boundaries may be roughened to reduce reflectivity with respect to the input light and the output light. Moreover, in some examples, one or more of the outer boundaries may be angled to reduce reflectivity with respect to the input light and the output light.

As shown in FIG. 14, the light emitters terminate in respective ends (e.g. end 150) opposite their footprints on substrate 105. The ends extend out of support material 135. Amplifier 1400 also comprises electrical contact 140 disposed on the support material and in electrical contact with the ends of the light emitters. Electrical contact 140 may be used to electrically bias one or more of the light emitters. In this description “electrically biasing” may also be referred to as “biasing”, in short.

As described above, in operation at least some of the light emitters may be electrically biased. When these biased light emitters are exposed to the input light, the input light may stimulate or cause the light emitters to then emit an emitted light having the same wavelength as the input light. In some examples, a subset of the light emitters may be reverse-biased. The magnitude of this reverse bias may be similar to, or different form, the magnitude of the bias. These reverse-biased light emitters may at least partially absorb one or more of the input light and the output light.

In some examples, the one or more reverse-biased light emitters may absorb the light propagating in the amplifier (i.e. at least a portion of the input light and the output light) and emit or generate a corresponding electrical signal. This absorption of the output light and the corresponding generation of the electrical signal may be used to sense or detect the input light. In this manner, the optical device may function as a combination amplifier and photodetector. Such a combination may be used in the case of weak optical signals, by first amplifying the input light and then detecting or sensing it.

To allow for enhanced amplification prior to the sensing, in some examples, a subset of the light emitters furthest downstream along the optical path may be reverse-biased to absorb the output light and emit a corresponding electrical signal. For example, referring to FIG. 14, in operation nanorod light emitters 120-1 to 120-6 may be biased, and light emitters 120-7 and 120-8 may be reverse biased. It is also contemplated that in some example, more, fewer or different light emitters may be biased, and more, fewer or different light emitters may be reverse biased.

Absorption of at least a portion of the output light by reverse-biased light emitters may also be used to modulate the output light; for example, by reducing the amplitude of the output light, or by turning it off. The ability to module the output light may also allow for pulsing the output light. As such, in some examples, a subset of the light emitters along the optical path may modulate the output light when the subset of the light emitters is reverse-biased.

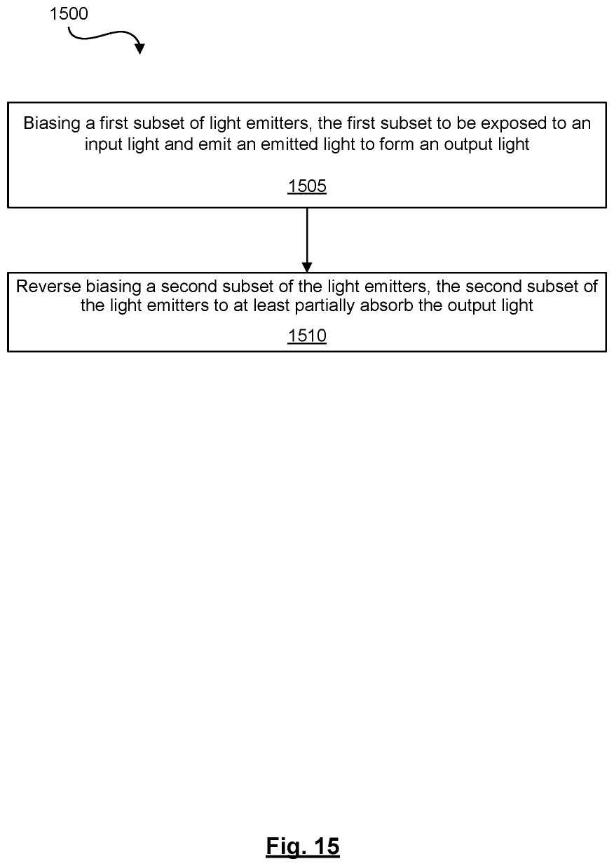

Turning now to FIG. 15, a flowchart is shown of an example method 1500 for operating an optical amplifier comprising a plurality of light emitters, such as amplifier 1400. At box 1505, a first subset of the light emitters may be biased. This first subset may be exposed to the input light and emit an emitted light to form the output light. At box 1510, a second subset of the light emitters may be reverse-biased. This second subset may at least partially absorb the output light.

As described above, the absorption of the output light by the reverse-biased light emitters may be used to one more of: module the amplitude of the output light and sense the output light. To enhance the combined amplification-and-sensing functionality, in some examples the reverse-biased subset of the light emitters may be furthest downstream along the optical path. In such examples, the method of operating the amplifier may include biasing the first subset of the light emitters furthest upstream along the optical path, and reverse biasing the second subset of the light emitters furthest downstream along the optical path. The second subset of the light emitters may at least partially absorb the output light and emit a corresponding electrical signal.

When the light emitters are electrically biased, in addition to light emission stimulated by the input light, they may also undergo spontaneous emission (SE) to spontaneously emit light. Such SE may be unrelated to the input light. Moreover, in some examples, the SE light may have a wavelength that is different than the wavelength of the input light. As such, SE light may represent parasitic light emission or noise in operation of an optical amplifier such as amplifier 1400.

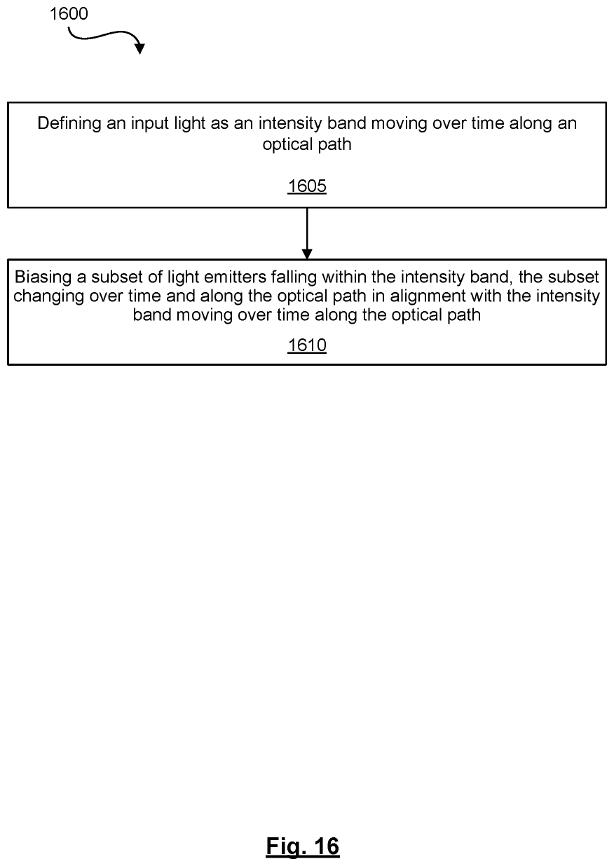

One way to reduce the SE noise and improve the signal to noise ratio in operation of the amplifier may be to electrically bias a subset of the light emitters that coincides with a light intensity band representing the input light signal. The remaining light emitters may be unbiased or reverse-biased. As the intensity band moves through the amplifier over time along the optical path, the subset of the biased light emitters may also change over time in alignment with the intensity band moving over time. This mode of operation is described further in relation to FIGS. 16 to 18C. By reducing the number of the light emitters electrically biased at any given time, this mode of operation may reduce SE noise during operation of the amplifier.

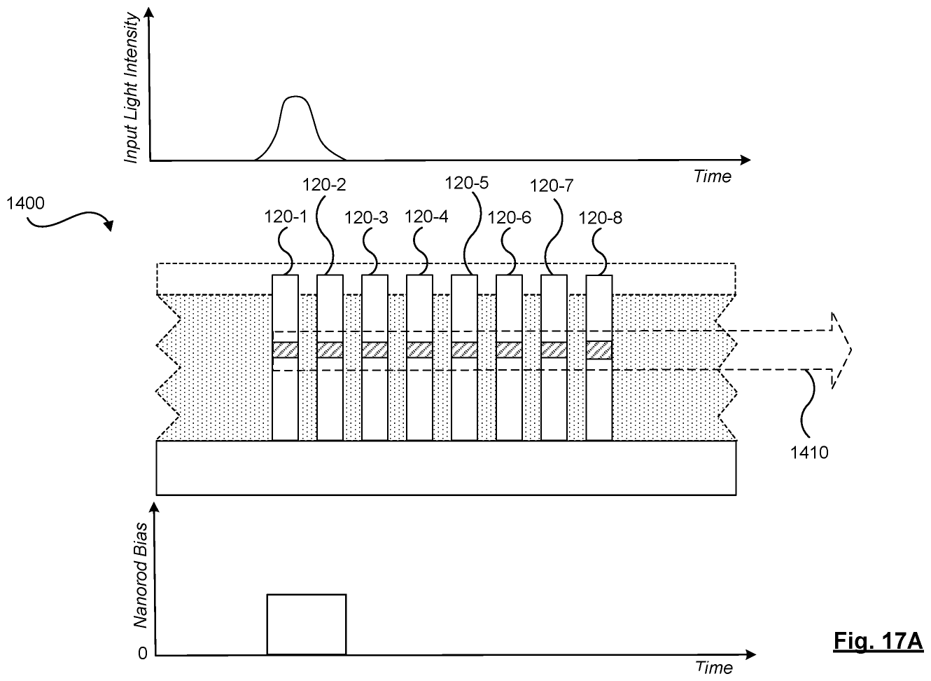

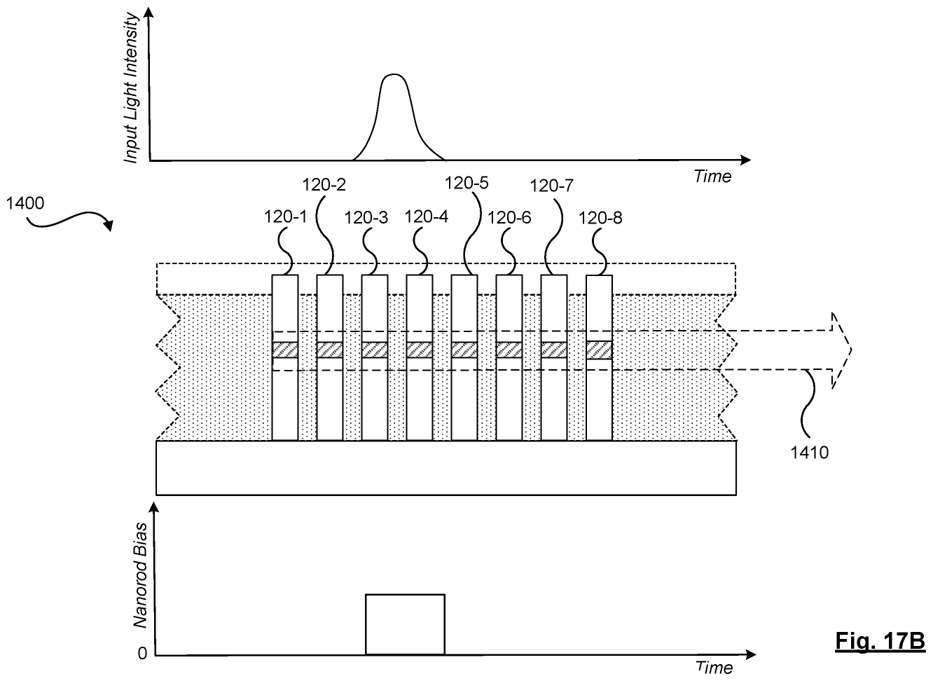

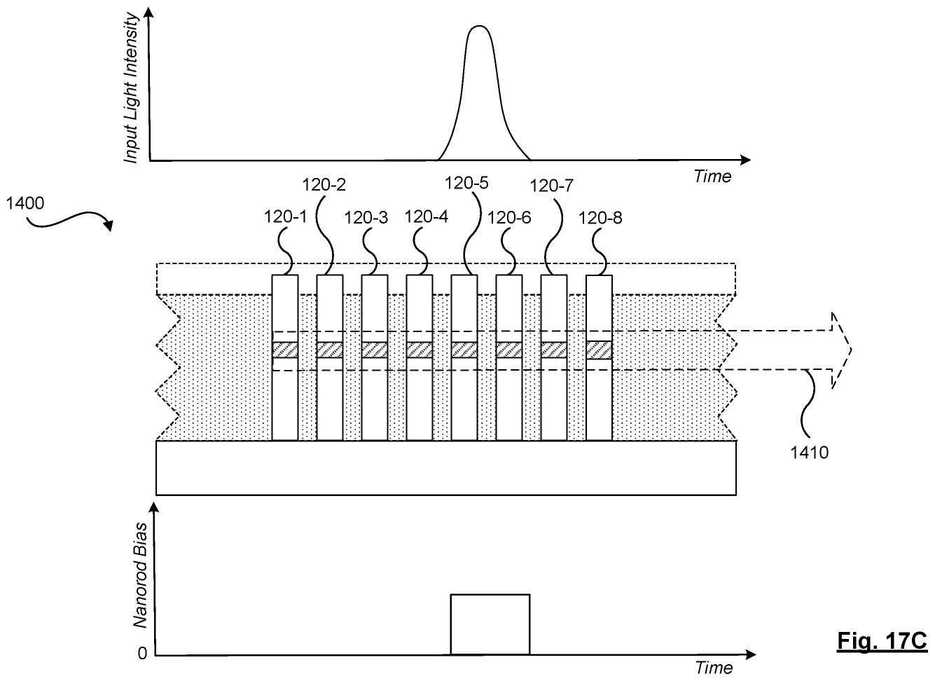

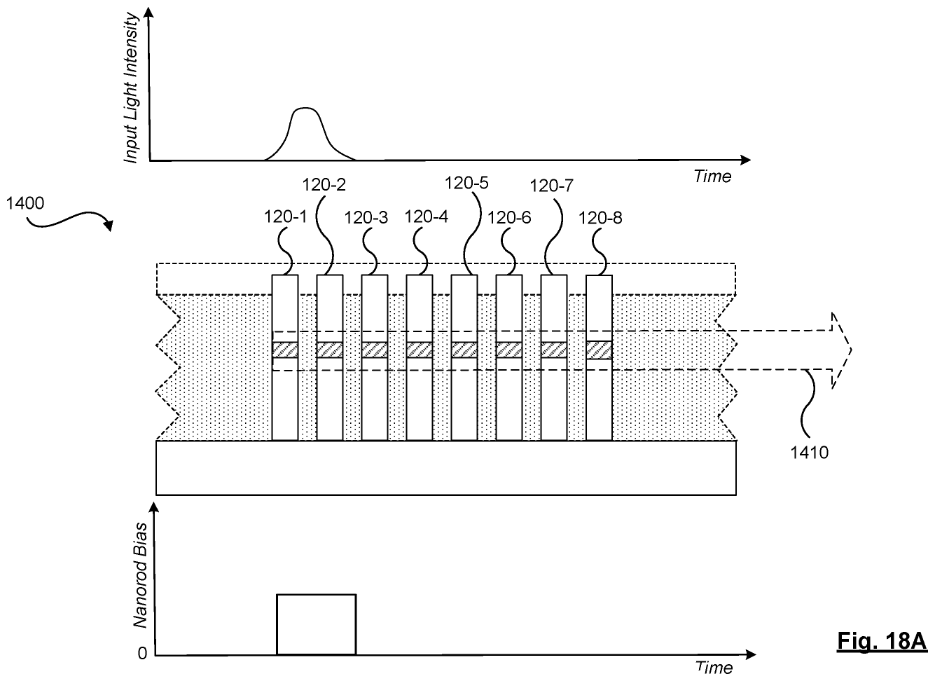

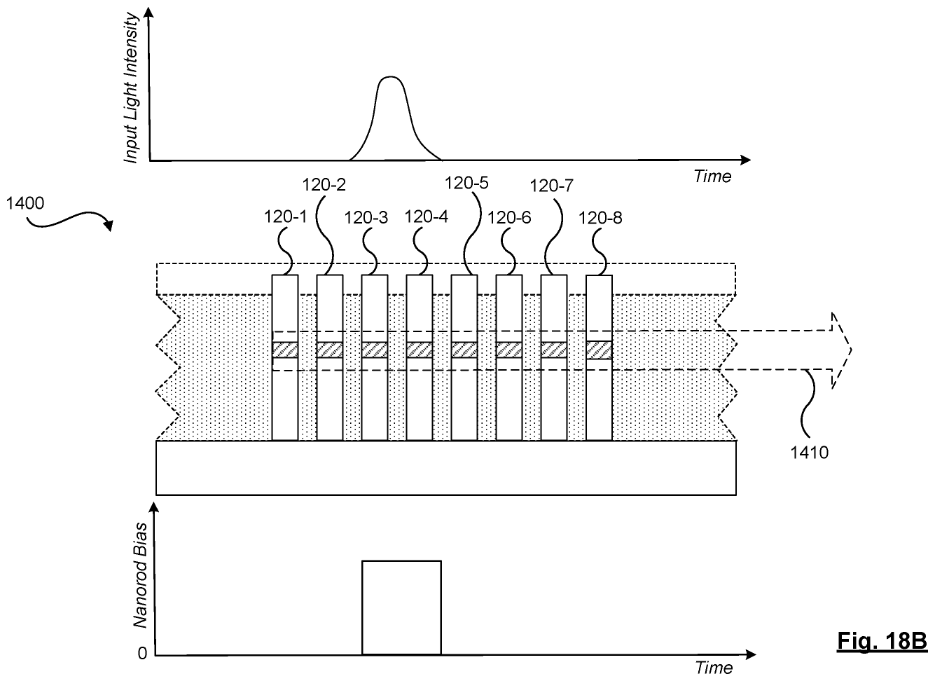

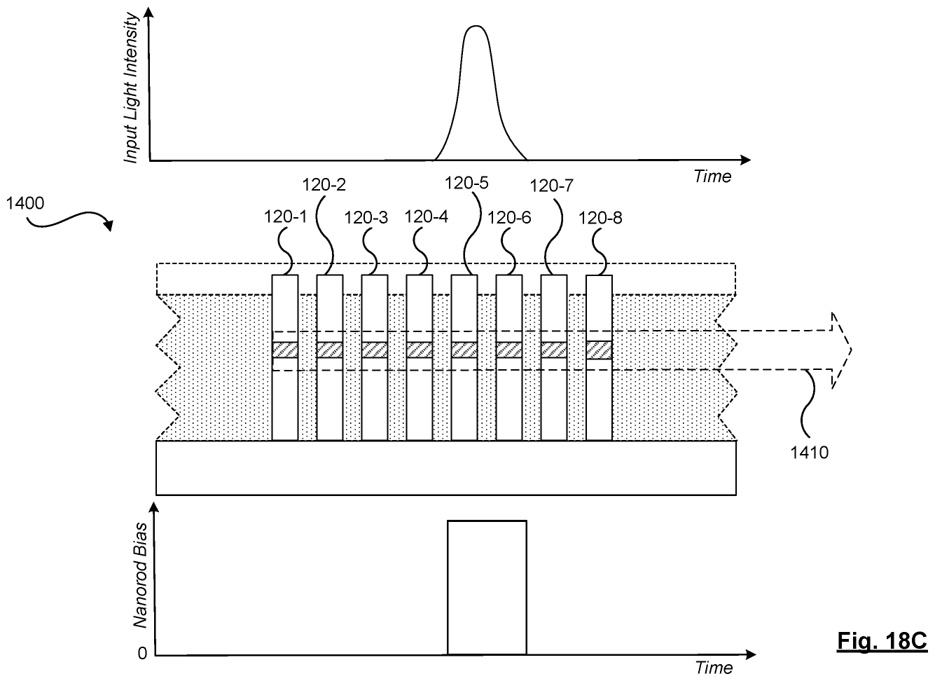

Turning now to FIG. 16, a flowchart is shown of an example method 1600 for operating an optical amplifier comprising a plurality of light emitters, such as amplifier 1400. At box 1605, the input light may be defined as an intensity band moving over time along the optical path. At box 1610, a subset of light emitters falling within the intensity band may be electrically biased. The subset may change over time and along the optical path in alignment with the intensity band moving over time along the optical path. Example implementations of method 1600 are described further in relation to FIGS. 17A to 18C.

FIGS. 17A to 17C show an example scheme for biasing a subset of the light emitters that fall within the intensity band of the input light. FIG. 17A shows amplifier 1400 at a time t₁, where the input light intensity band is aligned with a subset of the light emitters comprising nanorod light emitters 120-1 and 120-2. These same two nanorods are biased, while the remaining nanorod light emitters are unbiased. FIG. 17B shows amplifier 1400 at a later time t₂, where the input light intensity band has moved along the optical path and is aligned with another subset of the light emitters comprising nanorod light emitters 120-3 and 120-4. Nanorod light emitters 120-3 and 120-4 are the two nanorods that are biased, while the remaining nanorod light emitters are unbiased.

Moreover, FIG. 17C shows amplifier 1400 at a later time t₃, where the input light intensity band has moved further along the optical path and is aligned with yet another subset of the light emitters comprising nanorod light emitters 120-5 and 120-6. Nanorod light emitters 120-5 and 120-6 are the two nanorods that are biased, while the remaining nanorod light emitters are unbiased. As shown in FIGS. 17A to 17C, only the subset of the nanorod light emitters aligned with the intensity band of the input light are biased.

It is contemplated that in some examples, at any given time the intensity band may be aligned with a number of light emitters smaller or greater than two light emitters. While FIGS. 17A to 17C show only snapshots of the system at times t₁, t₂, and t₃, it is contemplated that other subsets of the nanorod light emitters may be biased, unbiased, or reverse biased at times t₁, t₂, t₃, and at other times. For example, another subset of the light emitters may be reverse biased to modulate or sense the output light. In some examples, in the combined amplifier-and-photodetector operating mode, the reverse biased subset may be furthest downstream along the optical path, and may absorb the output light and emit a corresponding electrical signal.

As the input signal propagates through the amplifier along the optical path, the signal becomes amplified by the stimulated emitted light from the biased light emitters and the intensity of the input light increases over time. This is shown in FIGS. 18A to 18C. In FIGS. 17A to 17C, the intensity of the input light is shown as constant, for ease of illustration. To increase the level of amplification of amplifier 1400, the nanorod light emitters may be biased at a greater magnitude. A side effect of this relatively higher-magnitude biasing may be increased SE noise. As the amplitude or intensity of the input light signal becomes stronger over time, the subsets of the light emitters may be biased at correspondingly larger magnitudes to increase amplification levels while maintaining the signal to SE noise ratio within acceptable levels. In other words, the subset of the light emitters may be biased at a biasing magnitude that increases over time and along the optical path. In this manner, as the signal becomes amplified and stronger over time, more SE noise may be tolerated in order to allow for greater levels of amplification, while maintaining signal to SE noise ratio within acceptable levels. Such increasing levels of light emitter subset biasing are shown in FIGS. 18A to 18C.

FIGS. 18A to 18C show another example scheme for biasing a subset of the light emitters that fall within the intensity band of the input light. FIG. 18A shows amplifier 1400 at a time t₁, where the input light intensity band is aligned with a subset of the light emitters comprising nanorod light emitters 120-1 and 120-2. These are the two nanorods that are biased at a magnitude v₁, while the remaining nanorod light emitters are unbiased. FIG. 18B shows amplifier 1400 at a later time t₂, where the input light intensity band has moved along the optical path and is aligned with another subset of the light emitters comprising nanorod light emitters 120-3 and 120-4. Nanorod light emitters 120-3 and 120-4 are the two nanorods that are biased at a greater magnitude v₂, while the remaining nanorod light emitters are unbiased.

Moreover, FIG. 18C shows amplifier 1400 at a yet later time t₃, where the input light intensity band has moved further along the optical path and is aligned with yet another subset of the light emitters comprising nanorod light emitters 120-5 and 120-6. Nanorod light emitters 120-5 and 120-6 are the two nanorods that are biased at a yet greater magnitude v₃, while the remaining nanorod light emitters are unbiased. As shown in FIGS. 18A to 18C, only the subset of the nanorod light emitters aligned with the intensity band of the input light are biased.

It is contemplated that in some examples, at any given time the intensity band may be aligned with a number of light emitters smaller or greater than two light emitters. While FIGS. 18A to 18C show only snapshots of the system at times t₁, t₂, and t₃, it is contemplated that other subsets of the nanorod light emitters may be biased, unbiased, or reverse biased at times t₁, t₂, t₃, and at other times. For example, another subset of the light emitters may be reverse biased to modulate or sense the output light. In some examples, in the combined amplifier-and-photo detector operating mode, the reverse biased subset may be furthest downstream along the optical path, and may absorb the output light and emit a corresponding electrical signal.

The amplifiers described herein may be used to amplify and detect an incoming optical signal. If the input light, emitted light, or the output light is allowed to interact with an analyte from the environment outside the amplifier, the amplifier may also be used to detect that analyte. For example, optical device 1200 shown in FIG. 12 may function as such an amplifier detector if the spacing with between the light emitters is set in a manner similar to that described in relation to FIG. 14, to allow optical device 1200 to act as an amplifier. Such an amplifier may comprise a cavity between two of the light emitters. This cavity may be in the optical path and open to a corresponding environment outside the optical device. The cavity may allow an analyte from the environment to enter the cavity and interact with one or more of the input light, the emitted light, and the output light.

Similarly, the ring resonator geometry described in relation to FIG. 13 may also be used as an amplifier if the spacing with between the light emitters is set in a manner similar to that described in relation to FIG. 14, to allow optical device 1300 to act as an amplifier.

It is also contemplated that in some examples the other optical device geometries described herein, for example those described in relation to FIGS. 3 to 11E, may also be used as amplifiers if the spacing between the light emitters or the relevant optical interfaces is adjusted in a manner similar to that described in relation to FIG. 14, to allow those devices to act as an amplifiers. For example, referring to FIGS. 5 and 6, in some examples optical dimension 530 may be set to be (q+¼)∧, where ∧ is the wavelength of the input light and q is an integer greater than or equal to zero. In this manner, the optical device of FIGS. 5 and 6 comprising nanowall 510 may be used as an amplifier. To further reduce the reflection of the input and output lights at first extremity 515 and second extremity 520, in some examples one or more of these extremities may be set at Brewster's angle.

In addition, it is contemplated that in some examples different light emitters, or different subsets of the light emitters, may be biased at different levels or magnitudes at the same time, to achieve different electro-optical effects. Moreover, in some examples, a subset of the nanorods may be biased to transparency (relative to the input and output lights). These nanorods could produce different optical effects; for example, they may act as a reflective Bragg back mirror to light having a wavelength other than that of the input and output lights. Other spatial arrangements of the light emitters, and other electrical biasing patterns, are also contemplated.

Throughout this specification and the appended claims, infinitive verb forms are often used. Examples include, without limitation: “to emit,” “to increase,” “to reduce,” and the like. Unless the specific context requires otherwise, such infinitive verb forms are used in an open, inclusive sense, that is as “to, at least, emit,” to, at least, increase,” “to, at least, reduce,” and so on.

The above description of illustrated example implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. Moreover, the various example implementations described herein may be combined to provide further implementations.

In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. An optical device to amplify an input light propagating along an optical path, the optical device comprising:
a substrate; and
a plurality of light emitters disposed on the substrate in the optical path, the light emitters each having a footprint on the substrate and extending away from the substrate laterally to the optical path, the light emitters each comprising a quantum well to emit an emitted light when the light emitter is electrically biased and exposed to the input light, the emitted light from the plurality of the light emitters to form an output light having an amplitude greater than a corresponding amplitude of the input light, and the light emitters each having a refractive index higher than a corresponding refractive index of an environment outside of and abutting the light emitters;
wherein:
the light emitters each comprise a nanorod; and
each pair of neighboring nanorods are spaced from one another along the optical path by a distance being about (q+¼)∧, where ∧ is a wavelength of the input light and q is an integer greater than or equal to zero.

2. The optical device of claim 1, further comprising a shell around one or more of the light emitters, wherein the one or more light emitters have a core-shell geometry.

3. The optical device of claim 2, wherein the shell is to reduce reflectivity of the light emitters of the input light.

4. The optical device of claim 3, wherein the shell has a thickness of about ∧/4 measured along the optical path.

5. The optical device of claim 1, further comprising a support material disposed on the substrate, one or more of the light emitters being at least partially embedded in the support material, the support material being substantially transparent to the input light and the output light, and the support material having a corresponding refractive index being smaller than the refractive index of the light emitters.

6. The optical device of claim 5, wherein the support material is a non-waveguide for the input light and the output light.

7. The optical device of claim 6, wherein outer boundaries of the support material are non-totally-internally-reflective of the input light and the output light.

8. The optical device of claim 7, wherein one or more of the outer boundaries are one or more of:
roughened to reduce reflectivity with respect to the input light and the output light; and
angled to reduce reflectivity with respect to the input light and the output light.

9. The optical device of claim 5, wherein:
the light emitters terminate in respective ends opposite their footprints on the substrate, the ends extending out of the support material; and
the optical device further comprising an electrical contact disposed on the support material and in electrical contact with the ends of the light emitters.

10. The optical device of claim 1, wherein a subset of the light emitters furthest downstream along the optical path is to absorb the output light and emit a corresponding electrical signal when the subset is reverse-biased.

11. The optical device of claim 1, wherein a subset of the light emitters along the optical path is to modulate the output light when the subset of the light emitters is reverse-biased.

12. The optical device of claim 1, further comprising a cavity between two of the light emitters, the cavity in the optical path and open to a corresponding environment outside the optical device, the cavity to allow an analyte from the corresponding environment to enter the cavity and interact with one or more of the input light and the output light.

13. A method of operating the optical device of claim 1, the method comprising:
defining the input light as an intensity band moving over time along the optical path; and,
biasing a subset of the light emitters falling within the intensity band, the subset changing over time and along the optical path in alignment with the intensity band moving over time along the optical path.

14. The method of claim 13, wherein the biasing the subset of the light emitters comprises biasing the subset of the light emitters at a biasing amplitude that increases over time and along the optical path.

15. The method of claim 13, further comprising:
reverse biasing a corresponding subset of the light emitters furthest downstream along the optical path, the corresponding subset of the light emitters to absorb the output light and emit a corresponding electrical signal.

16. A method of operating the optical device of claim 1, the method comprising:
biasing a first subset of the light emitters, the first subset to be exposed to the input light and emit the emitted light to form the output light; and
reverse biasing a second subset of the light emitters, the second subset of the light emitters to at least partially absorb the output light.

17. The method of claim 16, wherein:
the biasing the first subset of the light emitters comprises biasing the first subset of the light emitters furthest upstream along the optical path; and
the reverse biasing the second subset of the light emitters comprises reverse biasing the second subset of the light emitters furthest downstream along the optical path, the second subset of the light emitters to absorb the output light and emit a corresponding electrical signal.
